(19) United States
(12) Patent Application Publication
(10) Pub. No.: US 2026/0353851 A1
(43) Pub. Date: Nov. 5, 2026

(54) PHOTODETECTION ELEMENT

(71) Applicant: SONY SEMICONDUCTOR SOLUTIONS CORPORATION, KANAGAWA (JP)

(72) Inventors: YUTA OKABE, KANAGAWA (JP); SYUUITI TAKIZAWA, KANAGAWA (JP); OSAMU ENOKI, KANAGAWA (JP); MASAKI MURATA, KANAGAWA (JP); YOSHIYUKI HIRANO, KANAGAWA (JP)

(21) Appl. No.: 19/120,594

(22) PCT Filed: Oct. 10, 2023
(86) PCT No.: PCT/JP2023/036709

§ 371 Date: Apr. 11, 2025

(30) Foreign Application Priority Data
Oct. 18, 2022 (JP) 2022-167093

(51) Int. Cl. H10F 77/14; H10F 39/18; H10K 39/32

(52) U.S. Cl. CPC H10F 77/1433; H10F 39/18; H10K 39/32

(57) ABSTRACT

A first photodetection element (10) according to an embodiment of the present disclosure includes a first electrode (11), a second electrode (13), and a photoelectric conversion layer (12). The second electrode (13) is disposed to be opposed to the first electrode (11). The photoelectric conversion layer (12) is disposed between the first electrode (11) and the second electrode (13). The photoelectric conversion layer (12) includes fluorine and a binary semiconductor nanoparticle including indium. An atomic number ratio of indium/fluorine is within a range of 100 or more and 150 or less.

### TECHNICAL FIELD

The present disclosure relates to a photodetection element including a photoelectric conversion layer including quantum dots.

### BACKGROUND ART

For example, PTL 1 discloses a semiconductor film that is applied to an electronic device such as a solar cell or a light-emitting diode and that includes a metal ion and an aggregate of semiconductor quantum dots which include a metal atom and to which a thiocyanate ion is coordinated.

### CITATION LIST

### Patent Literature

PTL 1: Japanese Unexamined Patent Application Publication No. 2014-143397

### SUMMARY OF THE INVENTION

Incidentally, a photodetection element using a quantum dot is required to have improved heat resistance.

It is desirable to provide a photodetection element that makes it possible to improve heat resistance.

A first photodetection element according to an embodiment of the present disclosure includes a first electrode, a second electrode, and a photoelectric conversion layer. The second electrode is disposed to be opposed to the first electrode. The photoelectric conversion layer is disposed between the first electrode and the second electrode. The photoelectric conversion layer includes fluorine and a binary semiconductor nanoparticle including indium. An atomic number ratio of indium/fluorine is within a range of 100 or more and 150 or less.

A second photodetection element according to an embodiment of the present disclosure includes a first electrode, a second electrode, and a photoelectric conversion layer. The second electrode is disposed to be opposed to the first electrode. The photoelectric conversion layer is disposed between the first electrode and the second electrode. The photoelectric conversion layer includes a binary semiconductor nanoparticle including indium. A change in an absorption peak wavelength derived from the binary semiconductor nanoparticle after heating at 150 °C for 210 minutes is within a range of 0 nm or more and 20 nm or less.

A third photodetection element according to an embodiment of the present disclosure includes a first electrode, a second electrode, and a photoelectric conversion layer. The second electrode is disposed to be opposed to the first electrode. The photoelectric conversion layer is disposed between the first electrode and the second electrode, and includes a plurality of quantum dots. The plurality of quantum dots includes a core part and a plurality of ligands. The core part includes a binary semiconductor nanoparticle including indium. The plurality of ligands is coordinated to a surface of the core part. A surface coverage of the core part by the plurality of ligands is within a range of 84% or more and 100% or less.

In the first photodetection element according to an embodiment of the present disclosure, a photoelectric conversion layer is formed that includes fluorine and a binary semiconductor nanoparticle including indium, with an atomic number ratio of indium/fluorine being within a range of 100 or more and 150 or less. In the second photodetection element according to an embodiment of the present disclosure, a photoelectric conversion layer is formed using a binary semiconductor nanoparticle including indium; a change in an absorption peak wavelength derived from the binary semiconductor nanoparticle after heating at 150 °C for 210 minutes is within a range of 0 nm or more and 20 nm or less. In the third photodetection element according to an embodiment of the present disclosure, a photoelectric conversion layer is formed which includes a plurality of nanoparticles and in which a surface coverage of the core part by the plurality of ligands is within a range of 84% or more and 100% or less and the core part includes a binary semiconductor nanoparticle including indium. This allows for suppression of a decrease in light absorptivity after heating treatment.

### BRIEF DESCRIPTION OF THE DRAWINGS

FIG. 1 is a schematic cross-sectional view of an example of a configuration of a photodetection element according to a first embodiment of the present disclosure.

FIG. 2 is a schematic view of a configuration of a quantum dot constituting a photoelectric conversion layer illustrated in FIG. 1.

FIG. 3 is a schematic cross-sectional view of another example of the configuration of the photodetection element according to the first embodiment of the present disclosure.

FIG. 4 illustrates, as a reference example, an aggregation image in a film after heating of quantum dots.

FIG. 5 is an explanatory flowchart of a manufacturing process of the quantum dot (NOBF₄ treatment of a core part) illustrated in FIG. 3.

FIG. 6 is an explanatory flowchart of the manufacturing process of the quantum dot (ligand exchange treatment of the core part) subsequent to FIG. 5.

FIG. 7 is a block diagram illustrating an overall configuration of a photodetector of the present disclosure.

FIG. 8 is a schematic cross-sectional view of a configuration of each unit pixel of the photodetector illustrated in FIG. 7.

FIG. 9 is an equivalent circuit diagram of each unit pixel of the photodetector illustrated in FIG. 7.

FIG. 10 is a schematic cross-sectional view of an example of a configuration of a photodetection element according to a second embodiment of the present disclosure.

FIG. 11 is an explanatory diagram of an aspect of a plurality of quantum dots in the photoelectric conversion layer illustrated in FIG. 10.

FIG. 12 is an explanatory diagram of an aspect of a plurality of typical quantum dots in the layer.

FIG. 13 is a schematic cross-sectional view of a configuration of each unit pixel of a photodetector according to a modification example of the present disclosure.

FIG. 14 is a block diagram illustrating an example of a configuration of an electronic apparatus using the photodetector illustrated in FIG. 7.

FIG. 15A is a schematic view of an example of an overall configuration of a photodetection system using the photodetector illustrated in FIG. 7.

FIG. 15B is a diagram illustrating an example of a circuit configuration of the photodetection system illustrated in FIG. 15A.

FIG. 16 is a view depicting an example of a schematic configuration of an endoscopic surgery system.

FIG. 17 is a block diagram depicting an example of a functional configuration of a camera head and a camera control unit (CCU).

FIG. 18 is a block diagram depicting an example of schematic configuration of a vehicle control system.

FIG. 19 is a diagram of assistance in explaining an example of installation positions of an outside-vehicle information detecting section and an imaging section.

FIG. 20 is a diagram illustrating a change in an absorption spectrum before and after annealing of Experimental Example 1.

FIG. 21 is a diagram illustrating a change in an absorption spectrum before and after annealing of Experimental Example 2.

FIG. 22 is a diagram illustrating a change in an absorption spectrum before and after annealing of Experimental Example 3.

FIG. 23 is a characteristic diagram illustrating a relationship between a contained In/F atomic number ratio and a change rate of absorptivity.

FIG. 24 is a characteristic diagram illustrating a relationship between a contained In/F atomic number ratio and a wavelength change amount.

FIG. 25 is a characteristic diagram illustrating a relationship between an annealing temperature and sheet resistance of an upper electrode.

FIG. 26 is a characteristic diagram illustrating a relationship between a ligand coverage and a spectral variation amount.

FIG. 27 is a characteristic diagram illustrating a relationship between a ligand coverage and a PL intensity.

### MODES FOR CARRYING OUT THE INVENTION

In the following, description is given of embodiments of the present disclosure in detail with reference to the drawings. The following description is merely a specific example of the present disclosure, and the present disclosure should not be limited to the following aspects. Moreover, the present disclosure is not limited to arrangements, dimensions, dimensional ratios, and the like of each component illustrated in the drawings. It is to be noted that the description is given in the following order.
1. First Embodiment (An example of a photodetector including a photoelectric conversion layer using a quantum dot)
2. Second Embodiment (An example of a photodetector including a photoelectric conversion layer using a quantum dot)
3. Modification Example
4. Application Examples
5. Practical Application Examples
6. Example

### 1. FIRST EMBODIMENT

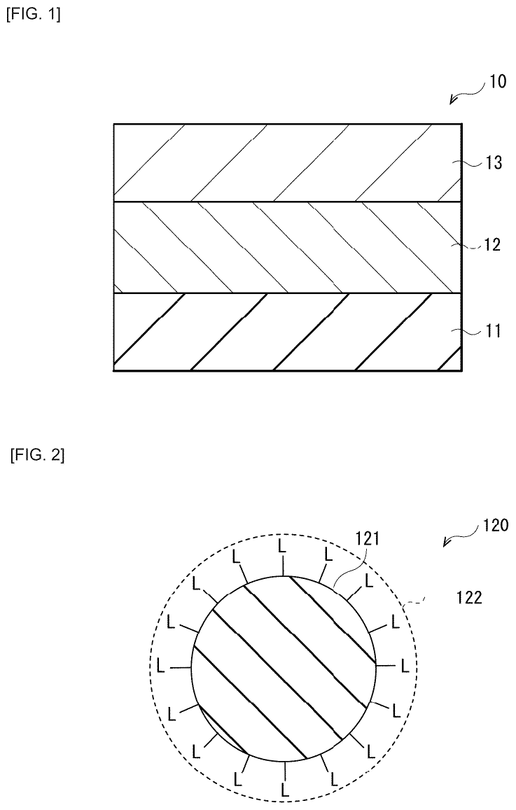

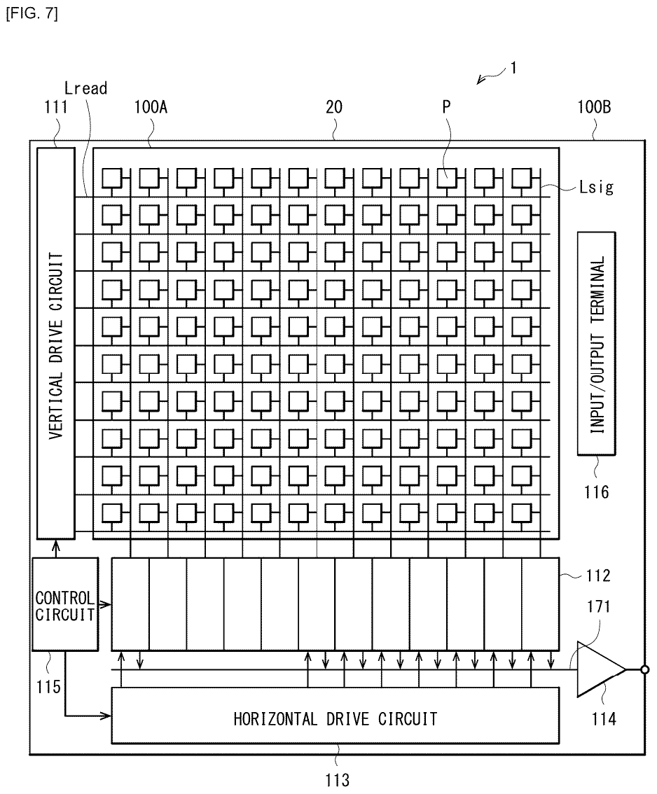

FIG. 1 schematically illustrates an example of a cross-sectional configuration of a photodetection element (a photodetection element 10) according to a first embodiment of the present disclosure. The photodetection element 10 constitutes one pixel (a unit pixel P) in a photodetector (a photodetector 1, e.g., see FIG. 7) such as a CMOS (Complementary Metal Oxide Semiconductor) image sensor used, for example, in an electronic apparatus such as a digital still camera or a video camera. The photodetection element 10 has a configuration in which a lower electrode 11, a photoelectric conversion layer 12, and an upper electrode 13 are stacked in this order. The photoelectric conversion layer 12 of the present embodiment includes fluorine (F) and a binary semiconductor nanoparticle including indium (In), and an In/F atomic number ratio is within a range of 100 or more and 150 or less.

### [Configuration of Photodetection Element]

The photodetection element 10 includes the photoelectric conversion layer 12 between the lower electrode 11 (e.g., first electrode) and the upper electrode 13 (e.g., second electrode) disposed to be opposed to each other. In the photodetection element 10, for example, electrons, among electron-hole pairs generated by photoelectric conversion, are read as signal charge from a side of the lower electrode 11. Hereinafter, description is given of a configuration, a material, and the like of each section by exemplifying a case in which electrons are read as signal charge from the side of the lower electrode 11.

The lower electrode 11 is configured by, for example, an electrically-conductive film having light transmissivity. Examples of a constituent material of the lower electrode 11 include indium tin oxide (ITO) that is In₂O₃ doped with tin (Sn) as a dopant. Examples of the constituent material of the lower electrode 11 include, in addition to the above, a tin oxide (SnO₂)-based material doped with a dopant, e.g., ATO doped with Sb as a dopant and FTO doped with fluorine as a dopant. In addition, zinc oxide (ZnO) or a zinc oxide-based material doped with a dopant may also be used. Examples of the ZnO-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Further, zinc oxide (IGZO, In—GaZnO₄) doped with indium and gallium as dopants may also be used. Additionally, as the constituent material of the lower electrode 11, CuI, InSbO₄, ZnMgO, CuInO₂, MgIN₂O₄, CdO, ZnSnO₃, TiO₂, or the like may also be used, or a spinel type oxide or an oxide having a YbFe₂O₄ structure may also be used.

In addition, in a case where light transmissivity is unnecessary for the lower electrode 11, a single metal or alloy may be used that has a low work function (e.g., φ=3.5 eV to 4.5 eV). Specific examples thereof include an alkali metal (e.g., lithium (Li), sodium (Na), and potassium (K), etc.) and a fluoride or oxide of such an alkali metal, and an alkali earth metal (e.g., magnesium (Mg) and calcium (Ca), etc.) and a fluoride or oxide of such an alkali earth metal. Other examples thereof include aluminum (Al), Al—Si—Cu alloy, zinc (Zn), tin (Sn), thallium (Tl), Na—K alloy, Al—Li alloy, Mg—Ag alloy, In, and a rare earth metal such as ytterbium (Yb), and an alloy of such a material.

Further examples of the material constituting the lower electrode 11 include electrically-conductive substances including a metal such as platinum (Pt), gold (Au), palladium (Pd), chromium (Cr), nickel (Ni), aluminum (Al), silver (Ag), tantalum (Ta), tungsten (W), copper (Cu), titanium (Ti), indium (In), tin (Sn), iron (Fe), cobalt (Co), or molybdenum (Mo), an alloy including such a metal element, an electrically-conductive particle of such a metal, an electrically-conductive particle of an alloy including such a metal, polysilicon containing impurities, a carbon-based material, an oxide semiconductor, a carbon nano-tube, and graphene. Other examples of the material constituting the lower electrode 11 include an organic material (electrically-conductive high polymer) such as poly(3,4-ethylenedioxythiophene)/polystyrene sulfonic acid [PEDOT/PSS]. In addition, a paste or ink obtained by mixing the above-mentioned material with a binder (high polymer) may be cured for use as an electrode.

The lower electrode 11 may be formed as a monolayer film or a stacked film including the above-mentioned material. A film thickness (hereinafter, simply referred to as a thickness) of the lower electrode 11 in a stacking direction is within a range of, for example, 20 nm or more and 200 nm or less, and preferably 30 nm or more and 150 nm or less.

The photoelectric conversion layer 12 converts optical energy into electric energy, and absorbs, for example, at least 60% or more of a predetermined wavelength included in a region from a visible light region to a near-infrared region to perform charge separation. The photoelectric conversion layer 12 absorbs, for example, 20% or more of light of wavelengths of some or all of the visible light region and the near-infrared light region at 900 nm or more and 1600 nm or less. The photoelectric conversion layer 12 is configured by a plurality of quantum dots 120. Specifically, the photoelectric conversion layer 12 including the quantum dots 120 includes F and a binary semiconductor nanoparticle including In, and the In/F atomic number ratio is within a range of 100 or more and 150 or less. Accordingly, a change in an absorption peak wavelength derived from the quantum dot 120 after heating at 150 °C for 210 minutes is reduced to a range of 0 nm or more and 20 nm or less. Description is given later of a detailed configuration of the quantum dot 120.

The photoelectric conversion layer 12 has a thickness of, for example, 10 nm or more and 300 nm or less, preferably 30 nm or more and 150 nm or less.

In the same manner as the lower electrode 11, the upper electrode 13 is configured by, for example, an electrically-conductive film having light transmissivity. In particular, the upper electrode 13 preferably has a transmittance of 50% or more and 100% or less for a wavelength of 900 nm or more and 1600 nm or less. In addition, the upper electrode 13 preferably has a resistivity of 0 mΩ·m or more and 3.8 mΩ·m or less. Examples of a constituent material of the upper electrode 13 include indium tin oxide (ITO) that is In₂O₃ doped with tin (Sn) as a dopant. As for the crystalline property, a thin film of the ITO may have a higher crystalline property, or may have a lower crystalline property (closer to amorphousness). Examples of the constituent material of the upper electrode 13 include, in addition to the above, a tin oxide (SnO₂)-based material doped with a dopant, e.g., ATO doped with Sb as a dopant and FTO doped with fluorine as a dopant. In addition, zinc oxide (ZnO) or a zinc oxide-based material doped with a dopant may also be used. Examples of the ZnO-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Further, zinc oxide (IGZO, In—GaZnO₄) doped with indium and gallium as dopants may also be used. Additionally, as the constituent material of the upper electrode 13, CuI, InSbO₄, ZnMgO, CuInO₂, MgIN₂O₄, CdO, ZnSnO₃, TiO₂, or the like may also be used, or a spinel-type oxide or an oxide having a YbFe₂O₄ structure may also be used.

In addition, in a case where light transmissivity is unnecessary for the upper electrode 13, a single metal or an alloy having a high work function (e.g., φ=4.5 eV to 5.5 eV) may be used. Specific examples thereof include Au, Ag, Cr, Ni, Pd, Pt, Fe, iridium (Ir), germanium (Ge), osmium (Os), rhenium (Re), tellurium (Te), and an alloy thereof.

Further examples of the material constituting the upper electrode 13 include electrically-conductive substances including a metal such as Pt, Au, Pd, Cr, Ni, Al, Ag, Ta, W, Cu, Ti, In, Sn, Fe, Co and Mo, an alloy including such a metal element, an electrically-conductive particle of such a metal, an electrically-conductive particle of an alloy including such a metal, polysilicon containing impurities, a carbon-based material, an oxide semiconductor, a carbon nano-tube, and graphene. Other examples of the material constituting the upper electrode 13 include an organic material (electrically-conductive high polymer) such as PEDOT/PSS. In addition, a paste or ink obtained by mixing the above-mentioned material with a binder (high polymer) may be cured for use as an electrode.

The upper electrode 13 may be formed as a monolayer film or a stacked film including the above-mentioned material. The upper electrode 13 has a thickness of, for example, 10 nm or more and 300 nm or less, preferably 10 nm or more and 100 nm or less.

It is to be noted that another layer may be provided between the lower electrode 11 and the upper electrode 13. 0 nm is a schematic illustration of another example (a photodetection element 10A) of the cross-sectional configuration of the photodetection element of the first embodiment of the present disclosure. For example, a hole block layer 14 may be provided between the lower electrode 11 and the photoelectric conversion layer 12. An electron block layer 15 and a work function adjustment layer 16 may be provided between the photoelectric conversion layer 12 and the upper electrode 13.

The hole block layer 14 selectively transports electrons, of charge carriers generated in the photoelectric conversion layer 12, to the lower electrode 11, and inhibits injection of holes from the side of the lower electrode 11. The hole block layer 14 may be formed using an organic compound, an oxide semiconductor, or a semiconductor nanoparticle. The organic compound is preferably an n-type semiconductor, and examples thereof include an organic metal dye complexed with an organic material and a transition metal ion represented by phthalocyanine zinc (II). Additionally, examples of the n-type semiconductor include fullerene or a derivative thereof, and a non-fullerene acceptor represented by an ITIC derivative and a BTP derivative. Examples of the oxide semiconductor and the semiconductor nanoparticle include inorganic materials such as titanium oxide (TiO₂), zinc oxide, zinc sulfide (ZnS), SrTiO₃, niobium oxide (Nb₂O₅), tungsten oxide (WO₃), indium oxide (In₂O₃), CuTiO₃, tin oxide (SnO₂), InGaZnO₄, InTiO₂, and β-Ga₂O₃.

The electron block layer 15 selectively transports holes, among the charge carriers generated in the photoelectric conversion layer 12, to the upper electrode 13, and inhibits injection of electrons from a side of the upper electrode 13. The electron block layer 15 may be formed using an organic compound, an oxide semiconductor, or a semiconductor nanoparticle. Examples of the organic compound include P3HT (poly(3-hexylthiophene-2,5-diyl)), SPIRO-OMeTAD, 2T-NATA, PTB7, PBTB-T, V886, PTB7-Th, Poly-TPD, and PBDB-T-2F. Examples of the oxide semiconductor and the semiconductor nanoparticle include nickel oxide, and Group I-V, Group I-III-VI, and Group I-II-III-VI compound semiconductors. The group I-V semiconductor nanoparticle includes, for example, Ag₂S and Ag₂Se. The group I-III-VI semiconductor nanoparticle includes, for example, AgInS₂, AgInSe₂, AgInTe₂, CuInS₂, CuInSe₂, and CuInTe₂. The group I-II-III-VI semiconductor nanoparticle includes, for example, ZnCuInS and ZnCuInSe.

The work function adjustment layer 16 has an electron affinity or a work function larger than the work function of the upper electrode 13. In addition, the work function adjustment layer 16 is directed to improving an electric bonding property between the electron block layer 15 and the upper electrode 13. The work function adjustment layer 16 may be formed using an organic compound, an oxide semiconductor, or a semiconductor nanoparticle. Examples of the organic compound include dipyrazino[2,3-f:2′,3′v-h]quinoxaline-2,3,6,7,10,11-hexacarbonitrile (HAT-CN), PEDOT/PSS, and polyaniline. Examples of the oxide semiconductor and the semiconductor nanoparticle include MoO₃, RuO₄, V₁O₅, and WO₃.

### [Configuration of Quantum Dot]

FIG. 2 schematically illustrates a cross-sectional configuration of the quantum dot 120. The quantum dot 120 is a core-shell quantum dot configured by a core part 121 and a shell layer 122, and the shell layer 122 includes a plurality of ligands L coordinated to a surface of the core part 121. In the photoelectric conversion layer 12 formed to have a layer shape using the plurality of quantum dots 120, the quantum dots 120 in the layer are adjacent to each other with the ligand L interposed therebetween.

The core part 121 is a semiconductor nanoparticle formed by the compound semiconductor. The core part 121 includes a binary semiconductor nanoparticle including indium (In). Specifically, the core part 121 includes indium arsenide (InAs).

The shell layer 122 includes the plurality of ligands L. The ligand L is an organic compound that forms a coordinate bond with a metal ion. The ligands L are coordinated to the surface of the core part 121 including InAs, thereby inactivating a highly reactive defect (dangling bond) present on the surface of the core part 121. The ligand L has one or both of a basic group and a weak acid group. The ligand L has, for example, one or both of a carboxyl group and a thiol group with a carbon number of 5 or less. Examples of such a ligand L include 1,3-benzenedithiol, 1,4-benzenedithiol, 3-mercaptopropionic acid (MPA), 1,2-ethanedithiol, malonic acid, succinic acid, 3-mercaptobenzoic acid, 4-mercaptobenzoic acid, 3-aminobenzenethiol, and 4-aminobenzenethiol.

It is to be noted that the plurality of ligands L coordinated to the surface of the core part 121 need not be single, but may include two or more of the above-mentioned organic compounds. In addition, when the length of the ligand L is increased, there is a possibility that the mobility of charge carriers between the quantum dots 120 may be decreased. Accordingly, the length of the ligand L is preferably 10 nm or less, for example.

Fluorine (F) included in the photoelectric conversion layer 12 described above is derived from nitrosonium tetrafluoroborate (NOBF₄) to be added at the time of ligand exchange described later. NOBF₄ is used, as a boron fluoride ion (BF₄⁻), to detach a large ligand at the time of synthesis of the quantum dot 120. When a desired ligand L is added to a dispersion liquid of InAs detached by BF₄⁻, ligand exchange proceeds, and the desired ligand L is bounded (coordinated) to the surface of the core part 121 including InAs.

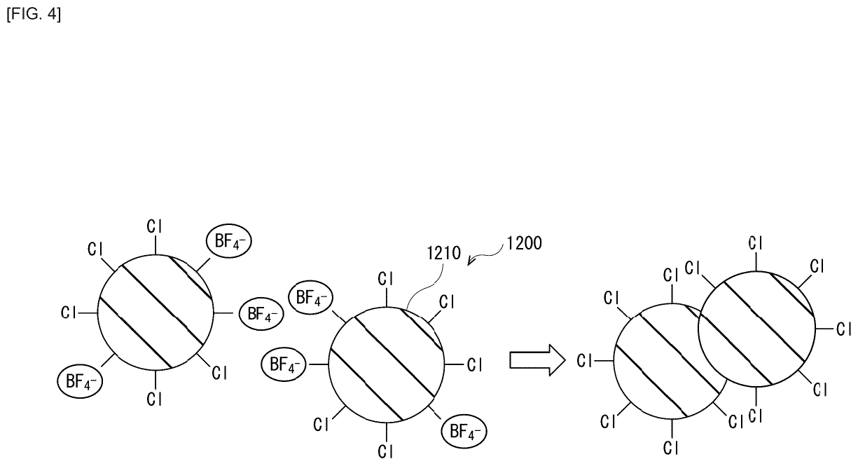

The content of F in the photoelectric conversion layer 12 represents the progress of the ligand exchange; it is considered that the lower content of F indicates more progress of the ligand exchange. FIG. 4 illustrates, as a reference example, an aggregation image of quantum dots 1200 in a film after heating of the quantum dots 1200. The ligand to be exchanged in the quantum dot 1200 is chlorine (Cl). There is a surface that has not been subjected to the exchange to the Cl ligand in the quantum dot 1200 having undergone the ligand exchange treatment. It is known that BF₄⁻ does not form a bond with a surface of a core part 1210 including InAs. Accordingly, InAs is exposed to the surface of the core part 1210 that has not been subjected to the exchange to the Cl ligand. It is presumed that the exposed part includes no shell layer 1220 that separates InAs nanoparticles (core parts 1210) from each other, thus causing aggregation to proceed easily at the time of heating. When the aggregation proceeds, an absorption spectrum (specifically, absorption peak wavelength) of quantum dots greatly changes, thus lowering light absorptivity in a desired wavelength range. In other words, sufficient progress of the ligand exchange allows an InAs nanoparticle surface to be covered with the ligand. As a result, the aggregation between InAs nanoparticles is suppressed, thus suppressing a decrease in light absorptivity after the heating.

In addition, BF₄⁻ is removed by washing in a process of the ligand exchange, but the aggregation is generated when the washing frequency is increased, as the In/F atomic number ratio reaches 150 or more. From those described above, the range that allows for sufficient heat resistance and does not cause generation of the aggregation in the ligand exchange process is a range of 100 or more and 150 or less in the In/F atomic number ratio.

As described above, in the photoelectric conversion layer 12 of the present embodiment, the In/F atomic number ratio is within a range of 100 or more and 150 or less. That is, the ligand exchange on the surface of the core part 121 including InAs sufficiently proceeds, thus reducing the change in the absorption peak wavelength derived from the quantum dot 120 after the heating at 150 °C for 210 minutes is reduced to a range of 0 nm or more and 20 nm or less. That is, the heat resistance is improved, and a decrease in light absorptivity after the heating is suppressed.

It is to be noted that the In/F atomic number ratio and the peak change amount have a correlation therebetween. In a typical quantum dot absorption peak shape, when the peak wavelength change amount exceeds 20 nm, the absorptivity in the absorption peak wavelength before the change is reduced by about 10%. As a result, the photoelectric conversion efficiency of the photodetection element is reduced by 10% or more with respect to a target wavelength. This is not an acceptable reduction value; it is desirable to suppress a decrease in the photoelectric conversion efficiency to 10% or less. For this reason, the In/F atomic number ratio is set to 100 or more.

In addition, the presence or absence of F in the photoelectric conversion layer 12 is confirmable by the presence or absence of a peak of BF₄⁻ by means of a time-of-flight secondary ion mass spectrometry. In/F can be calculated, for example, from an element number ratio obtained from peak intensities of F and In obtained by an X-ray photoelectron spectroscopy (XPS: X-ray Photoelectron Spectroscopy).

### [Method of Manufacturing Quantum Dot]

The quantum dot 120 may be manufactured using the following method, for example. It is to be noted that the following numerical values are exemplary and vary depending on materials and quantities to be used.

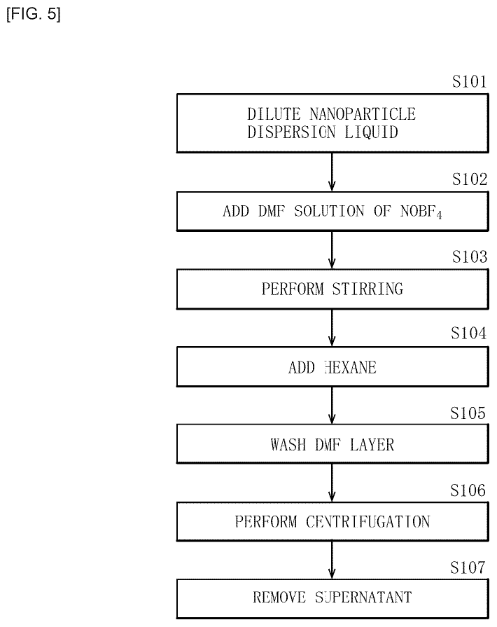

FIG. 5 illustrates steps of NOBF₄ treatment of the quantum dot 120. First, 1 mL of an InAs nanoparticle (InAs-NL, NL: Native Ligand) dispersion liquid is weighed into a 50 mL centrifuge tube, and 4 ml of hexane is added for dilution (step S101). Next, 6.25 mL of a DMF solution of 0.2 M NOBF₄, which has been prepared in advance, is added to the InAs nanoparticle dispersion liquid (step S102). Subsequently, the InAs nanoparticle dispersion liquid is stirred in a test tube mixer for 2 minutes (step S103).

Next, hexane is added to the InAs nanoparticle dispersion liquid to allow the total amount to be 40 ml (step S104). This causes the InAs nanoparticle dispersion liquid to be divided into a DMF layer (lower layer) and a hexane layer (upper layer), and the InAs nanoparticle moves to the DMF layer. It is to be noted that, in a case where the hexane layer is colored black, stirring is performed for another one minute in the test tube mixer to remove the hexane layer of the upper layer. Next, hexane is added again followed by stirring, and the DMF layer is washed (step S105). This process is repeated twice.

Subsequently, 25 ml of toluene is added to the DMF layer followed by stirring, and then centrifugation is performed at 4000 rpm for 5 minutes (step S106). Thereafter, a supernatant is removed (step S107). This allows for obtainment of an InAs (—BF₄⁻)(InAs-Naked) nanoparticle.

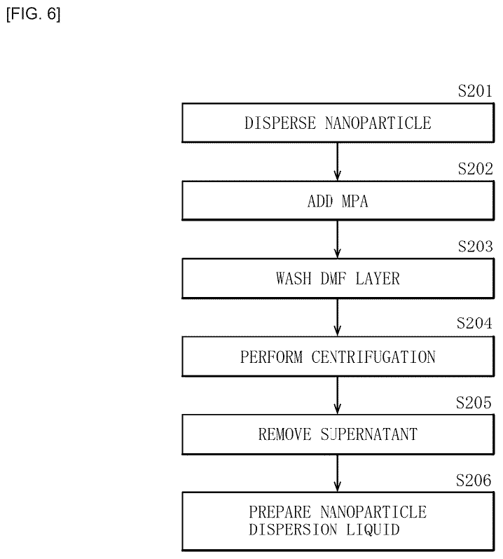

FIG. 6 illustrates steps of the ligand exchange treatment of the InAs (~BF₄⁻) (InAs-Naked) nanoparticle obtained by step S107. First, 5 ml of DMF is added to the InAs-Naked nanoparticle, followed by stirring for dispersion (step S201). Next, 250 μl of MPA is added as the ligand L to the dispersion liquid, followed by stirring for 3 minutes (step S202). Subsequently, in order to remove excess MPA, 10 ml of hexane is added to the dispersion liquid, followed by stirring. Thereafter, the stirred mixture is allowed to stand still to remove the hexane layer, and the DMF layer is washed (step S203). This process is repeated twice.

Next, 25 ml of toluene is added to the DMF layer followed by stirring, and then centrifugation is performed at 4000 rpm for 5 minutes (step S204). Thereafter, a supernatant is removed (step S205). Subsequently, 0.5 ml of DMF is added to the precipitate to prepare a dispersion liquid of InAs-MPA (quantum dot 120) (step S206).

After the dispersion liquid of the quantum dot 120 is prepared, a quantum dot film is formed First, a spin coater in a glove box is used to add 40 μl of the dispersion liquid of the quantum dot 120 dropwise onto a 1-inch quartz substrate having been subjected to a UV ozone treatment, and a quantum dot film is formed by a program at 1000 rpm for 60 sec from slope3 sec. After the film formation, heating at 60 °C for 5 minutes allows for removal of the solvent. This allows for obtainment of the photoelectric conversion layer 12 including the quantum dot 120.

### [Configuration of Photodetector]

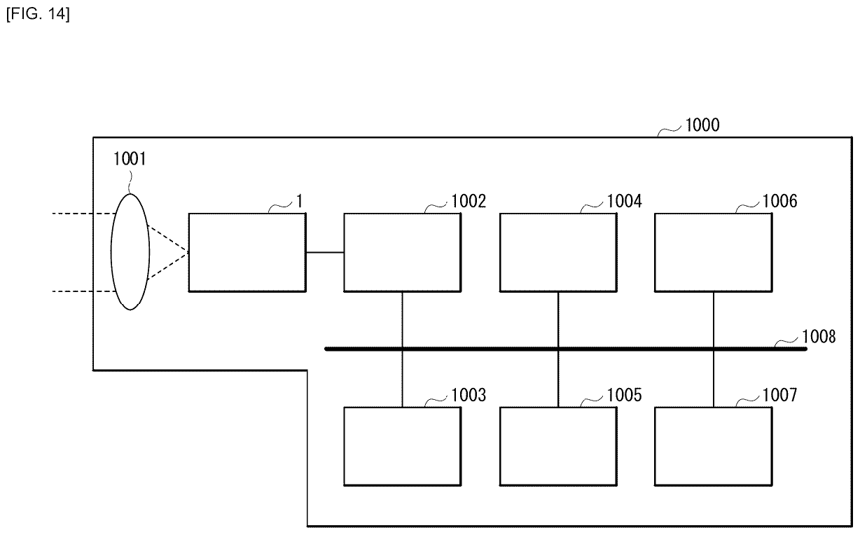

FIG. 7 illustrates an example of an overall configuration of the photodetector (photodetector 1) of the present disclosure. The photodetector 1 is used for an electronic apparatus (an electronic apparatus 1000, see FIG. 14) described later.

For example, the photodetector 1 takes in incident light (image light) from a subject via an optical lens system (unillustrated), and converts the amount of incident light formed as an image on an imaging surface into electric signals in units of pixels to output the electric signals as pixel signals. The photodetector 1 includes a pixel section 100A as an imaging area on a semiconductor substrate 20. In addition, the photodetector 1 includes, for example, a vertical drive circuit 111, a column signal processing circuit 112, a horizontal drive circuit 113, an output circuit 114, a control circuit 115, and an input/output terminal 116 in a peripheral region of this pixel section 100A.

The pixel section 100A includes, for example, a plurality of unit pixels P that is two-dimensionally arranged in matrix. The unit pixels P are provided, for example, with a pixel drive line Lread (specifically, a row selection line and a reset control line) for each of pixel rows and provided with a vertical signal line Lsig for each of pixel columns. The pixel drive line Lread transmits drive signals for reading signals from the unit pixels P. One end of the pixel drive line Lread is coupled to an output end of the vertical drive circuit 111 corresponding to each of the rows.

The vertical drive circuit 111 is a pixel drive section that is configured by a shift register, an address decoder, and the like and drives the unit pixels P of the pixel section 100A on a row-by-row basis, for example. Signals outputted from the respective unit pixels P in the pixel rows selectively scanned by the vertical drive circuit 111 are supplied to the column signal processing circuit 112 through the respective vertical signal lines Lsig. The column signal processing circuit 112 is configured by an amplifier, a horizontal selection switch, and the like provided for each of the vertical signal lines Lsig.

The horizontal drive circuit 113 is configured by a shift register, an address decoder, and the like. The horizontal drive circuit 113 drives horizontal selection switches of the column signal processing circuit 112 in order while scanning the horizontal selection switches. The selective scanning by this horizontal drive circuit 113 causes signals of the respective pixels transmitted through the respective vertical signal lines Lsig to be outputted to a horizontal signal line 117 in order and causes the signals to be transmitted to the outside of the semiconductor substrate 20 through the horizontal signal line 117.

The output circuit 114 performs signal processing on signals sequentially supplied from the respective column signal processing circuits 112 via the horizontal signal line 117, and outputs the signals. The output circuit 114 performs, for example, only buffering in some cases, and performs black level adjustment, column variation correction, various kinds of digital signal processing, and the like in other cases.

The circuit portion including the vertical drive circuit 111, the column signal processing circuit 112, the horizontal drive circuit 113, the horizontal signal line 117, and the output circuit 114 may be formed directly on the semiconductor substrate 20, or may be provided on an external control IC. In addition, the circuit portion may be formed in another substrate coupled by a cable or the like.

The control circuit 115 receives a clock supplied from the outside of the semiconductor substrate 20, data for an instruction about an operation mode, and the like and also outputs data such as internal information on the photodetector 1. The control circuit 115 further includes a timing generator that generates various timing signals, and controls driving of the peripheral circuits including the vertical drive circuit 111, the column signal processing circuit 112, the horizontal drive circuit 113, and the like on the basis of the various timing signals generated by the timing generator.

The input/output terminal 116 exchanges signals with the outside.

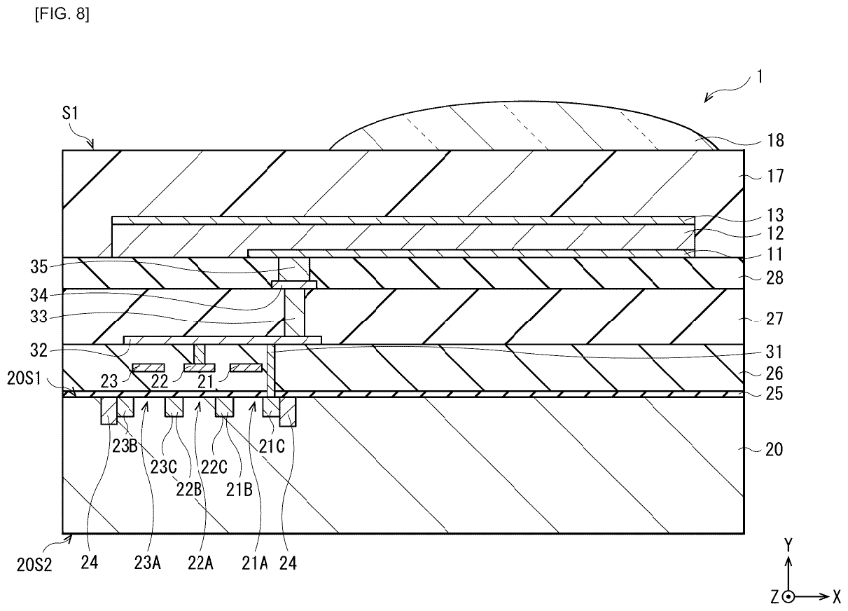

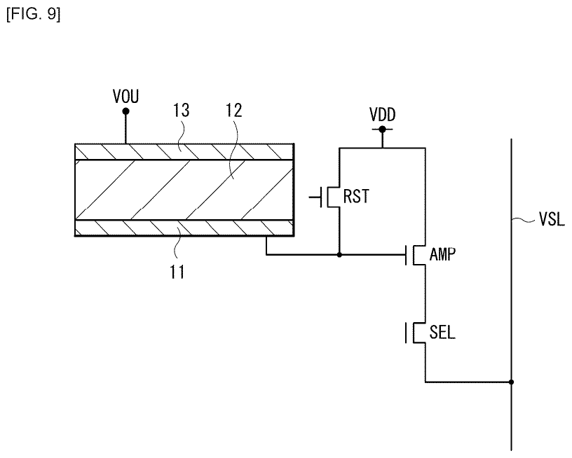

FIG. 8 schematically illustrates an example of a cross-sectional configuration of each unit pixel P of the photodetector 1 illustrated in FIG. 7. FIG. 9 is an equivalent circuit diagram of each unit pixel P of the photodetector 1 illustrated in FIG. 8.

The photodetector 1 includes, for example, a photoelectric conversion section on a side of a surface 20S1, which serves as a light incident side S1, of the semiconductor substrate 20 having a pair of surfaces (the surface 20S1 and a surface 20S2) opposed to each other. The photoelectric conversion section absorbs light corresponding to some or all of wavelengths of selective wavelength regions (e.g., a visible light region and a near-infrared region in a range of 900 nm or more and less than 1600 nm) and generates excitons (electron-hole pairs). The photoelectric conversion section is the above-described photodetection element 10, and includes the photoelectric conversion layer 12 between the lower electrode 11 and the upper electrode 13 that are disposed to be opposed to each other.

In the photodetection element 10, light incident on the photodetection element 10 from the side of the upper electrode 13 is absorbed by the photoelectric conversion layer 12. Excitons resulting therefrom are subjected to exciton separation to be dissociated into electrons and holes. Charge carriers (electrons and holes) generated here are transferred to respective different electrodes by diffusion due to a concentration difference between charge carriers or by an internal electric field due to a difference in the work function between an anode (e.g., the upper electrode 13) and a cathode (e.g., the lower electrode 11), and the transferred charge carriers are detected as a photocurrent. The transfer directions of electrons and holes are controlled by applying a potential between the lower electrode 11 and the upper electrode 13.

The semiconductor substrate 20 is configured by an n-type silicone (Si) substrate, for example. For example, the semiconductor substrate 20 includes, on the surface 20S1, a floating diffusion (floating diffusion layer) FD (a region 21C in the semiconductor substrate 20), an amplifier transistor (modulated element) AMP, a reset transistor RST, a selection transistor SEL, and an element separation region 24. In addition, a peripheral circuit (unillustrated) including a logic circuit or the like is provided in a peripheral part of the semiconductor substrate 20.

For example, an insulating layer 25 and interlayer insulating layers 26, 27, and 28 are provided in this order, on the side of the surface 20S1, between the surface 20S1 of the semiconductor substrate 20 and the lower electrode 11 of the photodetection element 10. A planarization layer 17 is provided on the upper electrode 13 of the photodetection element 10, and an optical member such as an on-chip lens 18 is disposed on the planarization layer 17.

A reset gate 21 of the reset transistor RST is disposed next to the floating diffusion FD (a region 21B). This enables the reset transistor RST to reset charge carriers accumulated in the floating diffusion FD.

The reset transistor RST resets charge carriers transferred from the photodetection element 10 to the floating diffusion FD, and is configured by a MOS transistor, for example. Specifically, the reset transistor RST is configured by the reset gate 21, a channel formation region 21A, and source/drain regions 21B and 21C. The reset gate 21 is coupled to a reset line, and one source/drain region 21C of the reset transistor RST also serves as the floating diffusion FD. The other source/drain region 21B that constitutes the reset transistor RST is coupled to a power supply VDD.

The amplifier transistor AMP is a modulation element that modulates the charge amount generated in the photodetection element 10 into a voltage, and is configured by, for example, a MOS transistor. Specifically, the amplifier transistor AMP is configured by an amplifier gate 22, a channel formation region 22A, and source/drain regions 22B and 22C. The amplifier gate 22 is coupled to the lower electrode 11 and one source/drain region 21C (floating diffusion FD) of the reset transistor RST, through a via and a through-wiring 31 provided in an interlayer insulating layer 26, wiring 32 and a through-wiring 33 provided in an interlayer insulating layer 27, and wiring 34, a contact 35, and the like provided in an interlayer insulating layer 28. In addition, one source/drain region 22C shares a region with the other source/drain region 21B that constitutes the reset transistor RST, and is coupled to the power supply VDD.

The selection transistor SEL is configured by a selection gate 23, a channel formation region 23A, and source/drain regions 23B and 23C. The section gate 23 is coupled to a selection line. In addition, one source/drain region 23V shares a region with the other source/drain region 22B constituting the amplifier transistor AMP, and the other source/drain region 23B is coupled to a signal line (data output line) VSL.

The reset line and the selection line are each coupled to a row scanning section 131 constituting the drive circuit. The signal line (data output line) VSL is coupled to a horizontal selection section 133 that constitutes the drive circuit.

The element separation region 24 has an STI (Shallow Trench Isolation) structure, and is configured by silicon oxide, for example.

The insulating layer 25 may be a film having positive fixed electric charge or a film having negative fixed electric charge. Examples of a material of the film having negative fixed electric charge include hafnium oxide, aluminum oxide, zirconium oxide, tantalum oxide, and titanium oxide. In addition, examples of an available material other than those mentioned above may include lanthanum oxide, praseodymium oxide, cerium oxide, neodymium oxide, promethium oxide, samarium oxide, europium oxide, gadolinium oxide, terbium oxide, dysprosium oxide, holmium oxide, thulium oxide, ytterbium oxide, lutetium oxide, yttrium oxide, an aluminum nitride film, a hafnium oxynitride film, and an aluminum oxynitride film.

For example, the interlayer insulating layers 26, 27, and 28 are each configured by a monolayer film including one of silicon oxide, silicon nitride, silicon oxynitride, or the like, or alternatively is configured by a stacked film including two or more thereof.

The reset gate 21, the amplifier gate 22, the selection gate 23, the through-wirings 31 and 33, the wirings 32 and 34, and the contact 35 are each configured by, for example, a doped silicon material such as PDAS (Phosphorus Doped Amorphous Silicon) or a metal material such as aluminum (Al), tungsten (W), titanium (Ti), cobalt (Co), hafnium (Hf), or tantalum (Ta).

The planarization layer 17 is configured by a material having light transmissivity, and is configured by, for example, a monolayer film including one of silicon oxide, silicon nitride, silicon oxynitride, or the like, or a stacked film including two or more thereof. The planarization layer 17 has a thickness of, for example, 100 nm to 30000 nm. In the same manner as the planarization layer 17, the on-chip lens 18 is configured by a material having light transmissivity.

### [Workings and Effects]

In the photodetection element 10 of the present embodiment, the photoelectric conversion layer 12 is formed which includes fluorine (F) and a binary semiconductor nanoparticle including indium (In), in which an In/F atomic number ratio is within a range of 100 or more and 150 or less. This prevents the aggregation of the plurality of quantum dots constituting the photoelectric conversion layer 12 due to heating, and suppresses a decrease in the light absorptivity after heating treatment. This is described below.

In recent years, development has progressed on a photodetector using quantum dots in a photoelectric conversion layer, in which an improvement in heat resistance of quantum dots is an issue. In order to improve the heat resistance of the quantum dots, suppression of aggregation of semiconductor nanoparticles constituting the quantum dots is generally a point. When the semiconductor nanoparticles are aggregated, a quantum confinement effect derived from quantum dots is diminished to thereby change an absorption spectrum shape, thus reducing the absorptivity.

Examples of past verifications of suppressing aggregation include an example in which quantum dots are embedded in a polymer to thereby improve heat resistance and an example in which the surface of a quantum dot is protected by an ALD (Atomic Layer Deposition) film to thereby suppress aggregation. However, the embedding in the polymer causes a decrease in concentration of the quantum dots in the film and an increase in a distance between the quantum dots, thus causing a decrease in mobility. In addition, the ALD film has issues of an increase in treatment time and an insufficient effect of an improvement in heat resistance.

Other than those described above, there is an example in which a glass-transition point of an organic material to be used for a carrier block layer on a quantum dot layer is defined to thereby improve heat resistance of the photodetection element, but the heat resistance itself depends on the quantum dot.

In contrast, in the present embodiment, for example, the photoelectric conversion layer 12 is formed using the quantum dot 120 in which the core part 121 includes a plurality of InAs nanoparticles, and the In/F atomic number ratio in the layer of the photoelectric conversion layer 12 is set to a range of 100 or more and 150 or less. This allows for suppression of aggregation of the plurality of quantum dots 120 constituting the photoelectric conversion layer 12 by heating, thus allowing a change in the absorption peak wavelength derived from the quantum dot 120 after the heating at 150 °C for 210 minutes to be reduced to a range of 0 nm or more and 20 nm or less, for example.

As described above, it is possible for the photodetection element 10 of the present embodiment to improve heat resistance.

In addition, in the photodetection element 10 of the present embodiment, the resistivity of the upper electrode 13 is set to a range of 0 mQ-m or more and 3.8 mQ-m or less. The improvement in the heat resistance of the photoelectric conversion layer 12 enables the upper electrode 13 to have improved electrical conductivity by means of crystallization. This makes it possible to improve quantum efficiency and responsivity.

Next, description is given of a second embodiment and a modification example of the present disclosure as well as application examples, practical application examples, and an example. It is to be noted that components corresponding to those of the photodetection element 10 and the photodetector 1 of the foregoing first embodiment are denoted by the same reference numerals, and descriptions thereof are omitted.

### 2. SECOND EMBODIMENT

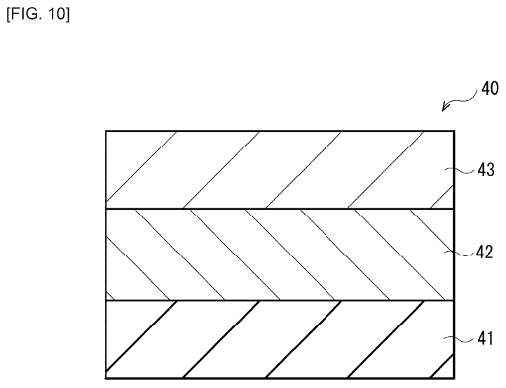

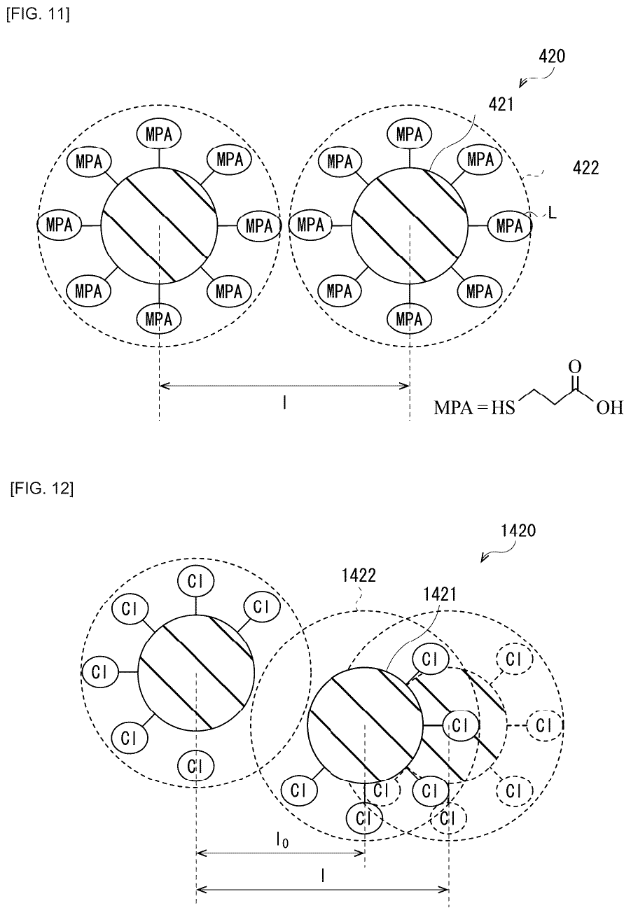

FIG. 10 schematically illustrates an example of a cross-sectional configuration of a photodetection element (a photodetection element 40) according to a second embodiment of the present disclosure. In the same manner as the foregoing first embodiment, the photodetection element 40 constitutes one pixel (unit pixel P) in a photodetector (e.g., photodetector 1) such as a CMOS image sensor used, for example, in an electronic apparatus such as a digital still camera or a video camera. The photodetection element 40 has a configuration in which a lower electrode 41, a photoelectric conversion layer 42, and an upper electrode 43 are stacked in this order. The photoelectric conversion layer 42 of the present embodiment includes a plurality of quantum dots 420 in which a surface coverage by the plurality of ligands L coordinated to a surface of a core part 421 including a binary semiconductor nanoparticle that includes indium (In) is within a range of 84% or more and 100% or less (see FIG. 11).

### [Configuration of Photodetection Element]

The photodetection element 40 includes the photoelectric conversion layer 42 between the lower electrode 41 (e.g., first electrode) and the upper electrode 43 (e.g., second electrode) disposed to be opposed to each other. In the photodetection element 40, for example, electrons, among electron-hole pairs generated by photoelectric conversion, are read as signal charge from a side of the lower electrode 41. Hereinafter, description is given of a configuration, a material, and the like of each section by exemplifying a case in which electrons are read as signal charge from the side of the lower electrode 41.

The lower electrode 41 is configured by, for example, an electrically-conductive film having light transmissivity. Examples of a constituent material of the lower electrode 41 include indium tin oxide (ITO) that is In₂O₃ doped with tin (Sn) as a dopant. Examples of the constituent material of the lower electrode 41 include, in addition to the above, a tin oxide (SnO₂)-based material doped with a dopant, e.g., ATO doped with Sb as a dopant and FTO doped with fluorine as a dopant. In addition, zinc oxide (ZnO) or a zinc oxide-based material doped with a dopant may also be used. Examples of the ZnO-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Further, zinc oxide (IGZO, In—GaZnO₄) doped with indium and gallium as dopants may also be used. Additionally, as the constituent material of the lower electrode 41, CuI, InSbO₄, ZnMgO, CuInO₂, MgIN₂O₄, CdO, ZnSnO₃, TiO₂, or the like may also be used, or a spinel type oxide or an oxide having a YbFe₂O₄ structure may also be used.

In addition, in a case where light transmissivity is unnecessary for the lower electrode 41, a single metal or alloy may be used that has a low work function (e.g., φ=3.5 eV to 4.5 eV). Specific examples thereof include an alkali metal (e.g., lithium (Li), sodium (Na), and potassium (K), etc.) and a fluoride or oxide of such an alkali metal, and an alkali earth metal (e.g., magnesium (Mg) and calcium (Ca), etc.) and a fluoride or oxide of such an alkali earth metal. Other examples thereof include aluminum (Al), Al—Si—Cu alloy, zinc (Zn), tin (Sn), thallium (Tl), Na—K alloy, Al—Li alloy, Mg—Ag alloy, In, and a rare earth metal such as ytterbium (Yb), and an alloy of such a material.

Further examples of the material constituting the lower electrode 41 include electrically-conductive substances including a metal such as platinum (Pt), gold (Au), palladium (Pd), chromium (Cr), nickel (Ni), aluminum (Al), silver (Ag), tantalum (Ta), tungsten (W), copper (Cu), titanium (Ti), indium (In), tin (Sn), iron (Fe), cobalt (Co), or molybdenum (Mo), an alloy including such a metal element, an electrically-conductive particle of such a metal, an electrically-conductive particle of an alloy including such a metal, polysilicon containing impurities, a carbon-based material, an oxide semiconductor, a carbon nano-tube, and graphene. Other examples of the material constituting the lower electrode 41 include an organic material (electrically-conductive high polymer) such as poly(3,4-ethylenedioxythiophene)/polystyrene sulfonic acid [PEDOT/PSS]. In addition, a paste or ink obtained by mixing the above-mentioned material with a binder (high polymer) may be cured for use as an electrode.

The lower electrode 41 may be formed as a monolayer film or a stacked film including the above-mentioned material. A film thickness (hereinafter, simply referred to as a thickness) of the lower electrode 41 in the stacking direction is within a range of, for example, 20 nm or more and 200 nm or less, and preferably 30 nm or more and 150 nm or less.

The photoelectric conversion layer 42 converts optical energy into electric energy, and absorbs, for example, at least 60% or more of a predetermined wavelength included in a region from a visible light region to a near-infrared region to perform charge separation. The photoelectric conversion layer 42 absorbs, for example, 20% or more of light of wavelengths of some or all of the visible light region and the near-infrared light region at 900 nm or more and 1600 nm or less. The photoelectric conversion layer 42 is configured by the plurality of quantum dots 420. As described in detail later, the quantum dot 420 is a core-shell quantum dot configured by the core part 421 and a shell layer 422, and the surface coverage by the plurality of ligands L constituting the shell layer 422 and being coordinated to the surface of the core part 421 including the binary semiconductor nanoparticle that includes indium (In) is within a range of 84% or more and 100% or less.

The photoelectric conversion layer 42 has a thickness of, for example, 10 nm or more and 300 nm or less, preferably 30 nm or more and 150 nm or less.

In the same manner as the lower electrode 41, the upper electrode 43 is configured by, for example, an electrically-conductive film having light transmissivity. In particular, the upper electrode 43 preferably has a transmittance of 50% or more and 100% or less for a wavelength of 900 nm or more and 1600 nm or less. In addition, the upper electrode 43 preferably has a resistivity of 0 mΩ·m or more and 3.8 mΩ·m or less. Examples of a constituent material of the upper electrode 43 include indium tin oxide (ITO) that is In₂O₃ doped with tin (Sn) as a dopant. As for the crystalline property, a thin film of the ITO may have a higher crystalline property, or may have a lower crystalline property (closer to amorphousness). Examples of the constituent material of the upper electrode 43 include, in addition to the above, a tin oxide (SnO₂)-based material doped with a dopant, e.g., ATO doped with Sb as a dopant and FTO doped with fluorine as a dopant. In addition, zinc oxide (ZnO) or a zinc oxide-based material doped with a dopant may also be used. Examples of the ZnO-based material include aluminum zinc oxide (AZO) doped with aluminum (Al) as a dopant, gallium zinc oxide (GZO) doped with gallium (Ga), boron zinc oxide doped with boron (B), and indium zinc oxide (IZO) doped with indium (In). Further, zinc oxide (IGZO, In—GaZnO₄) doped with indium and gallium as dopants may also be used. Additionally, as the constituent material of the upper electrode 43, CuI, InSbO₄, ZnMgO, CuInO₂, MgIN₂O₄, CdO, ZnSnO₃, TiO₂, or the like may also be used, or a spinel-type oxide or an oxide having a YbFe₂O₄ structure may also be used.

In addition, in a case where light transmissivity is unnecessary for the upper electrode 43, a single metal or an alloy having a high work function (e.g., φ=4.5 eV to 5.5 eV) may be used. Specific examples thereof include Au, Ag, Cr, Ni, Pd, Pt, Fe, iridium (Ir), germanium (Ge), osmium (Os), rhenium (Re), tellurium (Te), and an alloy thereof.

Further, examples of the material constituting the upper electrode 43 include electrically-conductive substances including a metal such as Pt, Au, Pd, Cr, Ni, Al, Ag, Ta, W, Cu, Ti, In, Sn, Fe, Co and Mo, an alloy including such a metal element, an electrically-conductive particle of such a metal, an electrically-conductive particle of an alloy including such a metal, polysilicon containing impurities, a carbon-based material, an oxide semiconductor, a carbon nano-tube, and graphene. Other examples of the material constituting the upper electrode 43 include an organic material (electrically-conductive high polymer) such as PEDOT/PSS. In addition, a paste or ink obtained by mixing the above-mentioned material with a binder (high polymer) may be cured for use as an electrode.

The upper electrode 43 may be formed as a monolayer film or a stacked film including the above-mentioned material. The upper electrode 43 has a thickness of, for example, 10 nm or more and 300 nm or less, preferably 10 nm or more and 100 nm or less.

It is to be noted that another layer may be provided between the lower electrode 41 and the upper electrode 43. In the same manner as the foregoing first embodiment, for example, the hole block layer 14 may be provided between the lower electrode 41 and the photoelectric conversion layer 42. The electron block layer 15 and the work function adjustment layer 16 may be provided between the photoelectric conversion layer 42 and the upper electrode 43.

### [Configuration of Quantum Dot]

As illustrated in FIG. 11, for example, the quantum dot 420 is a core-shell quantum dot configured by the core part 421 and the shell layer 422, and the shell layer 422 includes the plurality of ligands L coordinated to the surface of the core part 421. In the photoelectric conversion layer 42 formed to have a layer shape using the plurality of quantum dots 420, the quantum dots 420 in the layer are adjacent to each other with the ligand L interposed therebetween.

The core part 421 is a semiconductor nanoparticle formed by the compound semiconductor. The core part 421 includes a binary semiconductor nanoparticle including indium (In). Specifically, the core part 421 includes indium arsenide (InAs).

The shell layer 422 includes the plurality of ligands L. The ligand L is an organic compound that forms a coordinate bond with a metal ion. The ligands L are coordinated to the core part 421 including InAs, thereby inactivating a highly reactive defect (dangling bond) present on the surface of the core part 421. The ligand L has one or both of a basic group and a weak acid group. The ligand L has, for example, one or both of a carboxyl group and a thiol group with a carbon number of 5 or less. Examples of such a ligand L include 1,3-benzenedithiol, 1,4-benzenedithiol, 3-mercaptopropionic acid (MPA), 1,2-ethanedithiol, malonic acid, succinic acid, 3-mercaptobenzoic acid, 4-mercaptobenzoic acid, 3-aminobenzenethiol, and 4-aminobenzenethiol.

It is to be noted that the plurality of ligands L coordinated to the surface of the core part 421 need not be single, but may include two or more of the above-mentioned organic compounds. In addition, when the length of the ligand L is increased, there is a possibility that the mobility of charge carriers between the quantum dots 420 may be decreased. Accordingly, the length of the ligand L is preferably 10 nm or less, for example.

In the present embodiment, the plurality of quantum dots 420 constituting the photoelectric conversion layer 42 includes the core part 421 including the binary semiconductor nanoparticle including indium (In), and the surface coverage by the plurality of ligands L constituting the shell layer 422 is within a range of 84% or more and 100% or less.

It is obvious from a transmission electron microscope (TEM) and X-ray diffraction (XRD) that, in the quantum dot in which the core part includes the plurality of InAs nanoparticles (hereinafter, referred to as an InAs quantum dot), a particle diameter is maintained even in a case where spectral variation occurs by heating at 150 °C. It is found that the spectral variation of the InAs quantum dot is caused by a variation in a quantum effect and occurs only by a variation in an interparticle distance.

FIG. 11 illustrates an aspect of the plurality of quantum dots 420 in the layer of the photoelectric conversion layer 42 illustrated in FIG. 10. FIG. 12 illustrates an aspect of a plurality of quantum dots 1420 in a film including the quantum dots 1420 in which, for example, chlorine (Cl) is coordinated as a ligand. The above-mentioned organic compound including MPA exemplified as the ligand L of the present embodiment has a higher surface coverage (e.g., 80% or more) than a thiocyanate (SCN) or Cl to be used as a typical ligand. Therefore, in the quantum dot 1420 including, as a ligand, Cl with a low surface coverage, a core part 1410 is exposed to a portion of a surface of the core part 1410, as illustrated in FIG. 12. This exposed core part 1410 is fused, for example, by heating at 150 °C, and a distance between the core parts 1421 varies from a distance 1 to a distance l₀. In contrast, in the quantum dot 420 including, as the ligand L, MPA with a high surface coverage, for example, the distance 1 between the core parts 421 due to the heating at 150 °C remains constant without varying, as illustrated in FIG. 11. That is, in the photoelectric conversion layer 42 including the quantum dot 420 in which the surface coverage by the ligands L is 84% or more, the light absorptivity in an absorption peak derived from the quantum dot 420 is not decreased after the heating at 150 °C, for example, and photoluminescence (PL) intensity after the heating is maintained.

It is to be noted that, in a case where the surface coverage is calculated to exceed 100%, the calculation indicates that there are ligands that are not bonded to metal species. Due to low electrical conductivity, the ligand has a disadvantage in conduction of charge carriers.

The presence or absence of fusion of the above-described quantum dots 420 and 1420 may be determined from particle size analysis by XRD and TEM observation.

The surface coverage may be calculated from the following numerical expression (1):

(Numerical 1)

Surface coverage (%)=(number of ligands to be adsorbed [A])/(number of metal elements to be bonded to ligands on an outermost surface [B]) (1)

[A] may typically be calculated from a signal amount of 1H-NMR of a ligand. However, this calculation method of the surface coverage is unable to be used in a case of (1) being a short ligand and (2) having no H atoms, because a signal at 1H-NMR is unable to be detected. The MPA ligand corresponds to (1), and the Cl ligand and the SCN ligand correspond to (2).

Thus, in the present embodiment, it is found that [A] may be calculated from mass spectrometry and XPS. The molecular weight of the ligands, constituent elements and the numbers thereof may be identified and determined by MALDI-TOF mass spectrometry and isotope analysis thereof. The ligands are anionic species, and thus the use of Negative mode of the MALDI-TOF mass spectrometry enables selective detection of the anionic species. Therefore, analyzing isotopes and molecular weights of the ligands makes it possible to easily identify the constituent elements and the number thereof. In addition, it is possible, in the XPS, to identify the valence of an element from an emission peak (eV). It is possible to identify, using an XPS spectrum, elemental species turning into anionic species (element X⁻) and having an ionic bond with cationic species (In²⁺) of a quantum dot, among constituent elements of the ligands identified by the MALDI-TOF mass spectrometry. Calculation of a peak area ratio of elements identified from the above-described method allows [A] to be determined.

For example, the anionic species to be bonded to the cationic species of the quantum dot are turned into S⁻ in the MPA ligand and the SCN ligand, and turned into Cl⁻ in the Cl ligand. Accordingly, it can be considered that the peak area of S2p and the peak area of Cl2p in the XPS are, respectively, amounts of presence of the MPA and SCN ligands and the Cl ligand, which can be regarded as [A].

[B] may be calculated from an TEM image. The quantum dot is a single structure crystal, and thus, for example, InAs has a crystalline structure of four interatomic bonds and of a ratio of In atoms and As atoms being 1:1. The distance between In—As is known, and therefore a single grating size is unambiguously determined, thus making it possible to estimate the atomic number of metals on the outermost surface from the particle size calculated from the TEM image.

It is to be noted that, in a combination of metals with cations and anions, such as InAs, metal species that turn into cations are abundantly present on the outermost surface. One reason for this is that, on the outermost surface of quantum dot, anions of a ligand are coordinated to metal species with cations, thereby enabling the quantum dot to assume a stable state. In addition, in the InAs quantum dot, In assumes a state of 2+ and As assumes a state of 2−, and In²⁺ is able to be bonded to a peripheral ligand and is abundantly present as much as the number of metal atoms to be bonded to the ligand. This is also obvious from the peak area of In3d being larger than the peak area of As3d in bulk InAs by means of X-ray photoelectron spectroscopy (XPS); taking the difference enables [B] to be estimated.

It is possible to manufacture the quantum dot 420 using a method similar to that for the quantum dot 120 of the foregoing first embodiment.

### [Workings and Effects]

In the photodetection element 40 of the present embodiment, the photoelectric conversion element 42 is formed using the plurality of quantum dots 420 including the core part 421 including the binary semiconductor nanoparticle that includes indium (In), in which the surface coverage by the plurality of ligands L constituting the shell layer 422 is within a range of 84% or more and 100% or less. This allows for suppression of the variation in a distance between the quantum dots 420 in the layer of the photoelectric conversion layer 42 due to heating, thus reducing a decrease in the light absorptivity after the heating treatment.

As described above, it is possible for the photodetection element 40 of the present embodiment to improve heat resistance.

### 3. MODIFICATION EXAMPLE

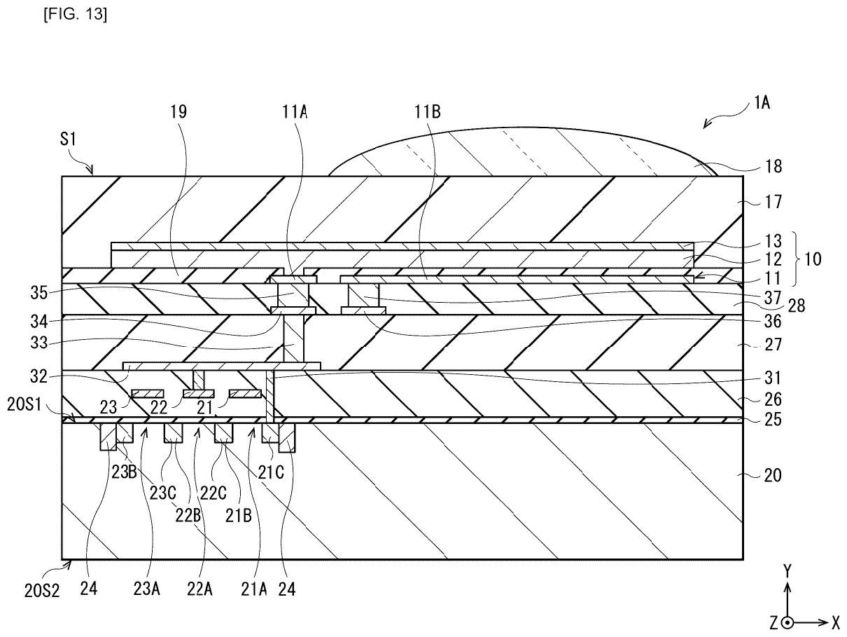

FIG. 13 schematically illustrates an example of a cross-sectional configuration of a photodetector (a photodetector 1A) according to a modification example of the present disclosure. In the same manner as the above-described photodetector 1, the photodetector 1A is used for an electronic apparatus (an electronic apparatus 1000, see FIG. 14) such as a CMOS image sensor used, for example, in an electronic apparatus such as a digital still camera or a video camera. The photodetector 1A of the present modification example differs from the photodetector 1 in that the lower electrode 11 includes a plurality of electrodes (e.g., two of a readout electrode 11A and an accumulation electrode 11B) and, for example, an insulating film 19 is provided between the lower electrode 11 and the photoelectric conversion layer 12.

The readout electrode 11A is directed to transferring electric charge generated in the photoelectric conversion layer 12 to the floating diffusion FD (region 21C). The readout electrode 11A is coupled to the floating diffusion FD via, for example, the through-wirings 31 and 33, the wirings 32 and 34, and the contact 35.

The accumulation electrode 11B is directed to accumulating electrons, among charge carriers generated in the photoelectric conversion layer 12, thereabove as signal charge. The accumulation electrode 11B is preferably larger than the readout electrode 11A, which enables electric charge to be accumulated abundantly. For example, the accumulation electrode 11B is coupled to a voltage application section (unillustrated) via wiring such as a wiring 36 and a contact 37.

The insulating film 19 is directed to electrically separating the accumulation electrode 11B and the photoelectric conversion layer 12 from each other. The insulating film 19 is provided on the interlayer insulating layer 28, for example, to cover the lower electrode 11. The insulating film 19 is provided with an opening on the readout electrode 11A, thereby allowing the readout electrode 11A and the photoelectric conversion layer 12 to be electrically coupled to each other.

The insulating film 19 is configured by, for example, a monolayer film including one of silicon oxide, silicon nitride, silicon oxynitride, or the like, or a stacked film including two or more thereof. The insulating film 19 has a thickness of 20 nm or more and 500 nm or less, for example.

It is to be noted that another layer may be provided between the insulating film 19 and the photoelectric conversion layer 12. For example, a semiconductor layer having a higher charge mobility and a larger bandgap than those of the photoelectric conversion layer 12 may be provided between the insulating film 19 and the photoelectric conversion layer 12. Examples of a material of the semiconductor layer include an oxide semiconductor such as IGZO and an organic semiconductor. Examples of the organic semiconductor include transition metal dichalcogenide, silicon carbide, diamond, graphene, a carbon nanotube, a condensed polycyclic hydrocarbon compound, and a condensed heterocyclic compound. Providing the semiconductor layer configured by the above-mentioned material allows signal charge generated in the photoelectric conversion layer 12 to be accumulated in the semiconductor layer, which reduces charge recombination at the time of charge accumulation, thus making it possible to improve transfer efficiency.

As described above, the configuration of the photodetector is not limited to the photodetector 1 of the foregoing embodiment; also in the photodetector 1A of the present modification example, it is possible to obtain effects similar to those of the foregoing first embodiment.

It is to be noted that, the example has been illustrated in which the photodetector 1A includes, as the photoelectric conversion section, the photodetection element 10 of the first embodiment. However, the photodetection element 40 of the second embodiment may also be used in the same manner as in the photodetector 1. The use of the photodetection element 40 as the photoelectric conversion section makes it possible to obtain effects similar to those of the foregoing second embodiment.

### 4. APPLICATION EXAMPLES

### Application Example 1

For example, the above-described photodetectors 1 and 1A are applicable, for example, to various types of electronic apparatuses including an imaging system such as a digital still camera and a video camera, a mobile phone having an imaging function, or another device having an imaging function.

FIG. 14 is a block diagram illustrating an example of a configuration of an electronic apparatus 1000.

As illustrated in FIG. 14, the electronic apparatus 1000 includes an optical system 1001, the photodetector (e.g., photodetector 1), and a DSP (Digital Signal Processor) 1002, and has a configuration in which the DSP 1002, a memory 1003, a display device 1004, a recording device 1005, an operation system 1006, and a power supply system 1007 are coupled together via a bus 1008, thus making it possible to capture a still image and a moving image.

The optical system 1001 includes one or a plurality of lenses, and takes in incident light (image light) from a subject to form an image on an imaging surface of the photodetector 1.

The above-described photodetector 1 or photodetector 1A is applied as the photodetector 1. The photodetector 1 converts the amount of incident light formed as an image on the imaging surface by the optical system 1001 into electric signals in units of pixels, and supplies the DSP 1002 with the electric signals as pixel signals.

The DSP 1002 performs various types of signal processing on the signals from the photodetector 1 to acquire an image, and causes the memory 1003 to temporarily store data on the image. The image data stored in the memory 1003 is recorded in the recording device 1005, or is supplied to the display device 1004 to display the image. In addition, the operation system 1006 receives various operations by the user, and supplies operation signals to the respective blocks of the electronic apparatus 1000. The power supply system 1007 supplies electric power required to drive the respective blocks of the electronic apparatus 1000.

### Application Example 2

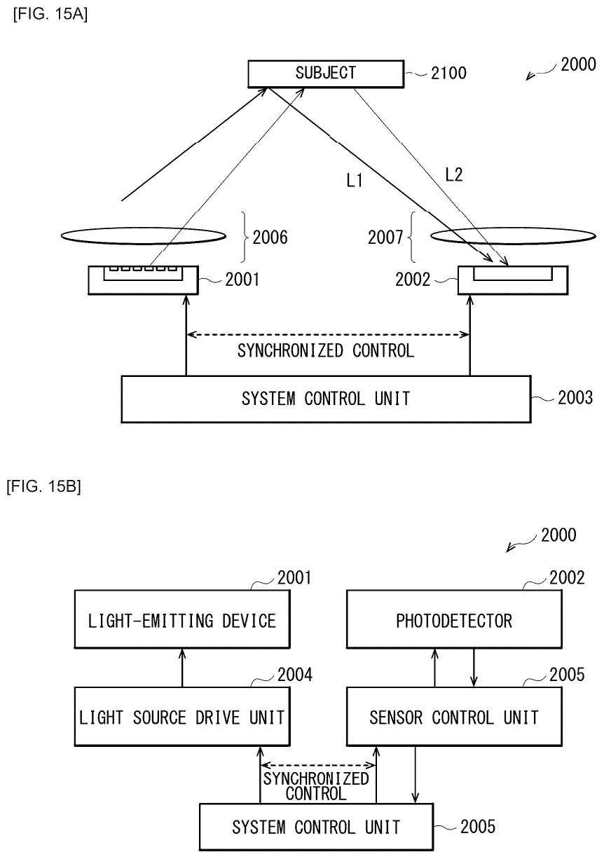

FIG. 15A schematically illustrates an example of an overall configuration of a photodetection system 2000 including the photodetector (e.g., photodetector 1). FIG. 15B illustrates an example of a circuit configuration of the photodetection system 2000. The photodetection system 2000 includes a light-emitting device 2001 as a light source unit that emits infrared light L2 and a photodetector 2002 as a light-receiving unit. For example, the above-described photodetector 1 may be used as the photodetector 2002. The photodetection system 2000 may further include a system control unit 2003, a light source drive unit 2004, a sensor control unit 2005, a light source side optical system 2006, and a camera side optical system 2007.

The photodetector 2002 is able to detect light L1 and light L2. The light L1 is reflected light of ambient light from the outside reflected by a subject (measurement target) 2100 (FIG. 15A). The light L2 is light reflected by the subject 2100 after having been emitted by the light-emitting device 2001. The light L1 is, for example, visible light, and the light L2 is, for example, infrared light. The light L1 is detectable at the photoelectric conversion section in the photodetector 2002, and the light L2 is detectable at a photoelectric conversion region in the photodetector 2002. It is possible to acquire image information on the subject 2100 from the light L1 and to acquire information on a distance between the subject 2100 and the photodetection system 2000 from the light L2. For example, the photodetection system 2000 can be mounted on an electronic apparatus such as a smartphone or on a mobile body such as a car. The light-emitting device 2001 can be configured by, for example, a semiconductor laser, a surface-emitting semiconductor laser, or a vertical resonator surface-emitting laser (VCSEL). An iTOF method can be employed as a method for the photodetector 2002 to detect the light L2 emitted from the light-emitting device 2001; however, this is not limitative. In the iTOF method, the photoelectric conversion section is able to measure a distance to the subject 2100 by time of flight of light (Time-of-Flight; TOF), for example. As a method for the photodetector 2002 to detect the light L2 emitted from the light-emitting device 2001, it is possible to adopt, for example, a structured light method or a stereovision method. For example, in the structured light method, light having a predetermined pattern is projected on the subject 2100, and distortion of the pattern is analyzed, thereby making it possible to measure the distance between the photodetection system 2000 and the subject 2100. In addition, in the stereovision method, for example, two or more cameras are used to acquire two or more images of the subject 2100 viewed from two or more different viewpoints, thereby making it possible to measure the distance between the photodetection system 2000 and the subject. It is to be noted that it is possible for the system control unit 2003 to synchronously control the light-emitting device 2001 and the photodetector 2002.

### 5. PRACTICAL APPLICATION EXAMPLES

### (Example of Practical Application to Endoscopic Surgery System)

The technology according to an embodiment of the present disclosure (present technology) is applicable to various products. For example, the technology according to an embodiment of the present disclosure may be applied to an endoscopic surgery system.

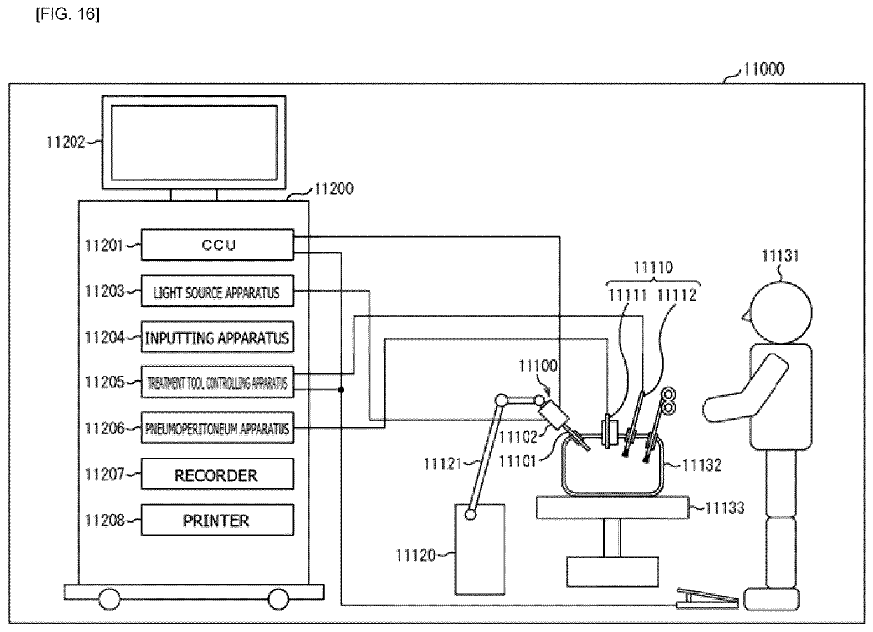

FIG. 16 is a view depicting an example of a schematic configuration of an endoscopic surgery system to which the technology according to an embodiment of the present disclosure (present technology) can be applied.

In FIG. 16, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

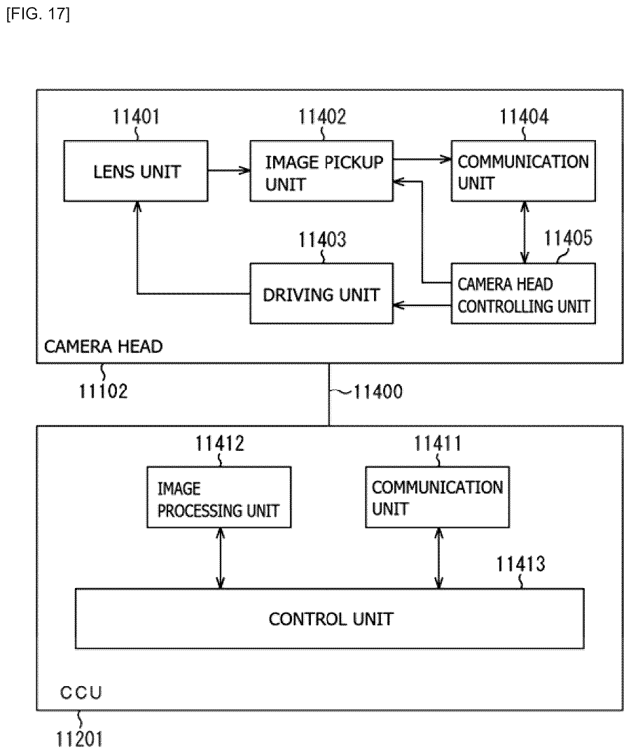

FIG. 17 is ablock diagram depicting an example of a functional configuration of the camera head 11102 and the CCU 11201 depicted in FIG. 16.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The description has been given above of one example of the endoscopic surgery system, to which the technology according to an embodiment of the present disclosure is applicable. The technology according to an embodiment of the present disclosure is applicable to, for example, the image pickup unit 11402 of the configurations described above. Applying the technology according to an embodiment of the present disclosure to the image pickup unit 11402 makes it possible to improve detection accuracy.

It is to be noted that although the endoscopic surgery system has been described as an example here, the technology according to an embodiment of the present disclosure may also be applied to, for example, a microscopic surgery system, and the like. (Example of Practical Application to Mobile Body)

The technology according to an embodiment of the present disclosure (present technology) is applicable to various products. For example, the technology according to an embodiment of the present disclosure may be achieved in the form of an apparatus to be mounted to a mobile body of any kind. Non-limiting examples of the mobile body may include an automobile, an electric vehicle, a hybrid electric vehicle, a motorcycle, a bicycle, any personal mobility device, an airplane, an unmanned aerial vehicle (drone), a vessel, a robot, a construction machine, and an agricultural machine (tractor).

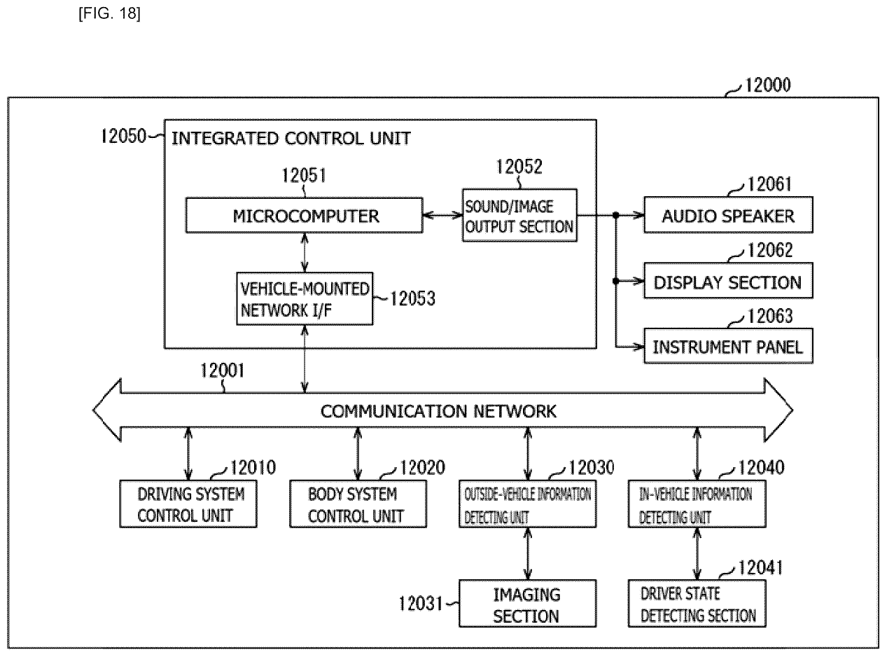

FIG. 18 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 18, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 18, an audio speaker 12061, a display section 12062, and an instrument panel 12063 are illustrated as the output device. The display section 12062 may, for example, include at least one of an on-board display and a head-up display.

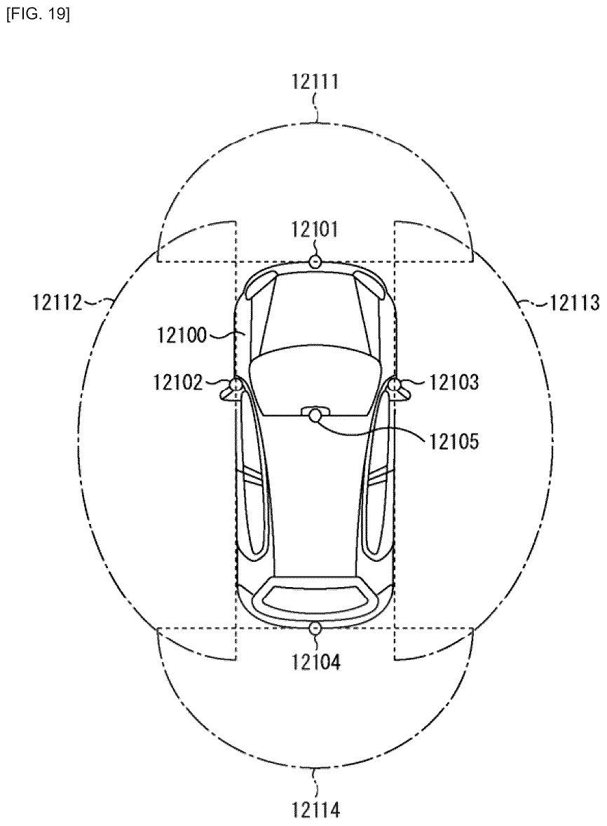

FIG. 19 is a diagram depicting an example of the installation position of the imaging section 12031.

In FIG. 19, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 19 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The description has been given hereinabove of one example of the mobile body control system, to which the technology according to an embodiment of the present disclosure may be applied. The technology according to an embodiment of the present disclosure may be applied to the imaging section 12031 among components of the configuration described above. Specifically, the photodetector (e.g., photodetector 1) according to any of the foregoing embodiments and modification example thereof is applicable to the imaging section 12031. The application of the technology according to an embodiment of the present disclosure to the imaging section 12031 allows for a high-definition captured image with less noise, thus making it possible to perform highly accurate control utilizing the captured image in the mobile body control system.

### 6. EXAMPLE

### [Experiment 1]

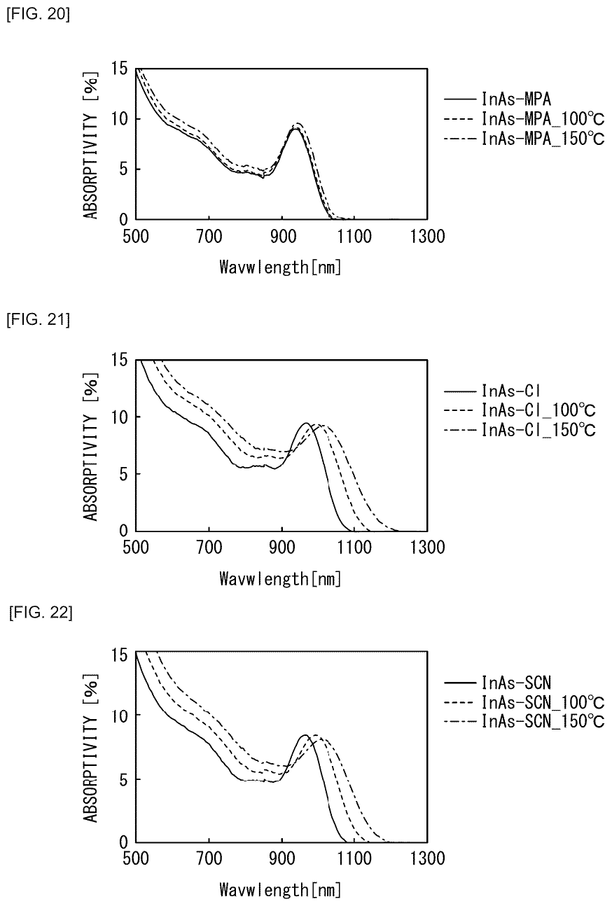

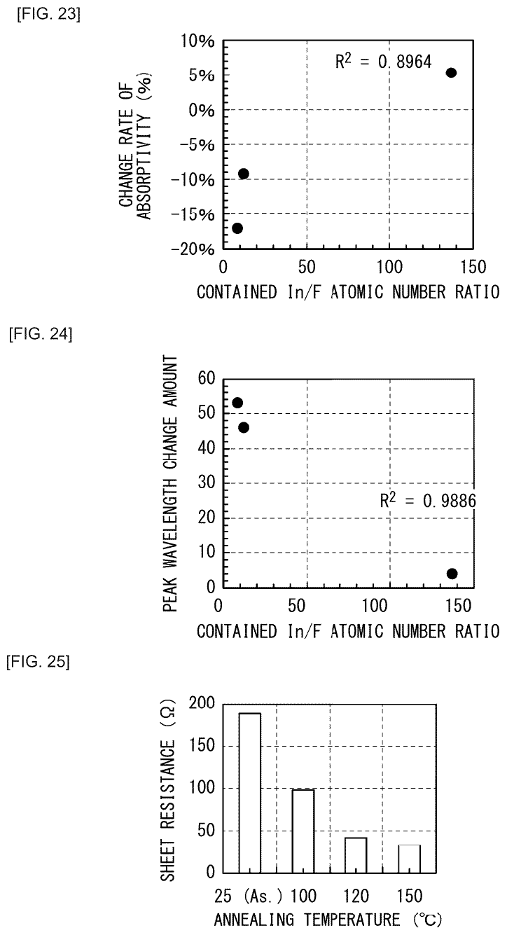

FIGS. 20 to 22 each illustrate, as Experimental Examples 1 to 3, a change in an absorption spectrum before and after annealing treatment at 150 °C for 3.5 hours by forming, as a film, a quantum dot prepared using the above-described method. The absorption spectrum was measured using a JASCO V770 apparatus. Table 1 summarizes types of a semiconductor nanoparticle (core part) and ligands used in Experimental Examples 1 to 3, In/F atomic number ratio, a shift amount of an absorption peak wavelength, and a change rate of light absorptivity for a peak wavelength before annealing. FIG. 23 is a characteristic diagram illustrating a relationship between a contained In/F atomic number ratio and the change rate of light absorptivity for a peak wavelength before annealing (change rate of absorptivity). FIG. 24 is a characteristic diagram illustrating a relationship between the contained In/F atomic number ratio and a change amount of the absorption peak wavelength.

TABLE 1

| | | | | Change Rate of |
|---|---|---|---|---|
| | Core | | Shift Amount | Light Absorptivity |
| | Part - | | of Absorption | for Peak Wavelength |
| | Ligand | In/F | Peak Wavelength | before Annealing |
| Experimental | InAs- | 137 | 4 nm | +5.3% |
| Example 1 | MPA | | | |
| Experimental | InAs- | 12.1 | 46 nm | −9.2% |
| Example 2 | SCN | | | |
| Experimental | InAs- | 8.4 | 56 nm | −17.1% |
| Example 3 | Cl | | | |

It was appreciated, from FIGS. 23 and 24 and Table 1, that a smaller content rate of F leads to a smaller change in the absorption peak after the heating. That is, it was appreciated that the smaller content of F leads to an improvement in heat resistance.

FIG. 25 is a characteristic diagram illustrating a relationship between an annealing temperature and sheet resistance of an upper electrode. It was appreciated, from FIG. 25, that, for example, the upper electrode including ITO is crystallized increasingly by heating at a high temperature, thus resulting in lowered sheet resistance. That is, the improvement in heat resistance of the quantum dot enables an improvement in electrical conductivity of the upper electrode by heating, thus making it possible to improve quantum efficiency and responsivity.

### [Experiment 2]

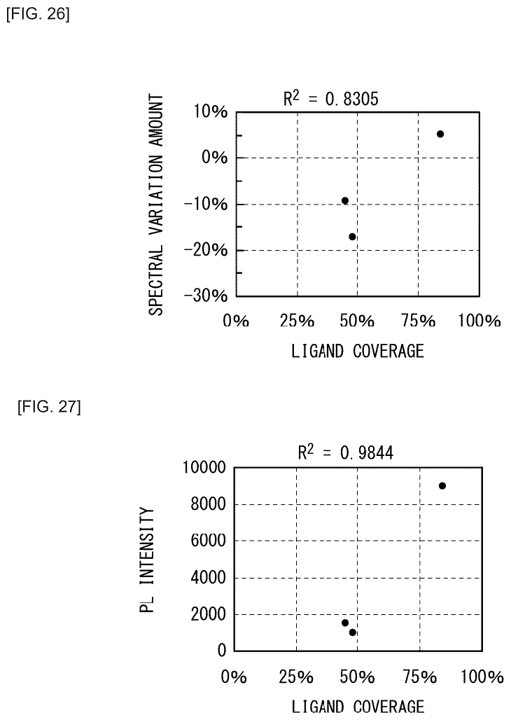

As Experimental Examples 4 to 6, a quantum dot prepared using the above-described method was formed as a film, and a surface coverage by ligands on a surface of the core part was calculated. In addition, the absorption spectrum before and after annealing treatment at 150 °C for 3.5 hours in each of Experimental Examples 4 to 6 was measured to calculate a change rate of light absorptivity for a peak wavelength before the annealing. Further, PL intensity after the annealing treatment at 150 °C for 3.5 hours was measured. Table 2 summarizes types of a semiconductor nanoparticle (core part) and ligands used in Experimental Examples 4 to 6, a coverage (surface coverage) by ligands, a change rate of light absorptivity (spectral variation amount) for a peak wavelength before the annealing treatment, and PL intensity after the annealing treatment. FIG. 26 is a characteristic diagram illustrating a relationship between a surface coverage by ligands (ligand coverage) and a spectral variation amount before and after the annealing treatment. FIG. 27 is a characteristic diagram illustrating a relationship between the ligand coverage and the PL intensity after the annealing treatment.

TABLE 2

| | | | Change Rate of | |
|---|---|---|---|---|
| | Core | | Light Absorptivity | |
| | Part - | Surface | for Peak Wavelength | PL |
| | Ligand | Coverage | before Annealing | Intensity |
| Experimental | InAs- | 84% | +5.3% | 9000 |
| Example 4 | MPA | | | |
| Experimental | InAs- | 45% | −9.2% | 1550 |
| Example 5 | SCN | | | |
| Experimental | InAs- | 48% | −17.1% | 1050 |
| Example 6 | Cl | | | |

It was confirmed, from FIGS. 26 and 27 and Table 2, that higher surface coverage leads to a smaller change in the absorption spectrum. In addition, it was confirmed that higher surface coverage leads to higher PL intensity. That is, it was appreciated that higher surface coverage leads to improved heat resistance.

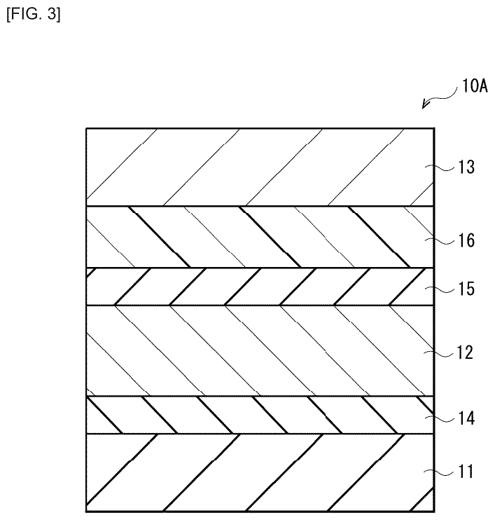

Description has been given hereinabove of the present technology by referring to the first and second embodiments, the modification example, the application examples, the practical application examples, and Example; however, the content of the present disclosure is not limited to the foregoing embodiments and the like, and may be modified in a wide variety of ways. For example, the foregoing embodiments and the like exemplify electrons being read as signal charge from the side of the lower electrode 11, but this is not limitative; holes may be read as signal charge from the side of the lower electrode 11. In that case, the stacking order of the layers of the photodetection element 10A illustrated in FIG. 3 is inverted. That is, the photodetection element 10A has a configuration in which the layers are stacked in order from the side of the upper electrode 13 toward the light incident side Si.

In addition, in the photodetector 1 and the like mentioned as the photodetector of the present disclosure, the semiconductor substrate 20 may be provided with one or a plurality of photoelectric conversion sections (inorganic photodiodes) that detects light of a wavelength region different from the photodetection element 10.

Further, although the foregoing embodiments and the like exemplify the configuration of the front side illumination imaging element, the content of the present disclosure is also applicable to a back side illumination imaging element.

Furthermore, all the components described in the foregoing embodiments and the like may not be included in the electronic apparatus 1000 and the photodetector 1 of the present disclosure; conversely, other components may be included therein. For example, the electronic apparatus 1000 may be provided with a shutter directed to controlling incidence of light on the photodetector 1, or may be equipped with an optical cut filter depending on purposes of the electronic apparatus 1000.

In addition, although the foregoing embodiments and the like exemplify the application of the quantum dot 120 to the photodetector 1, the quantum dot 120 of the present disclosure may be applied to a solar cell. In the case of the application to the solar cell, the photoelectric conversion layer 12 including an aggregate of the quantum dots 120 is preferably designed to broadly absorb a wavelength of 400 nm to 800 nm, for example.

It is to be noted that the effects described herein are merely exemplary and are not limitative, and may further include other effects.

It is to be noted that the present technology may also have the following configurations. According to the present technology of the following configurations, the decrease in the light absorptivity after the heating treatment is suppressed. It is therefore possible to improve heat resistance.
(1)

A photodetection element including:
a first electrode;
a second electrode disposed to be opposed to the first electrode; and
a photoelectric conversion layer disposed between the first electrode and the second electrode, the photoelectric conversion layer including fluorine and a binary semiconductor nanoparticle including indium, with an atomic number ratio of indium/fluorine being within a range of 100 or more and 150 or less.
(2)

The photodetection element according to (1), in which
the photoelectric conversion layer includes a plurality of quantum dots, and
the plurality of quantum dots includes a core part and a plurality of ligands, the core part including a binary semiconductor nanoparticle including the indium, the plurality of ligands being coordinated to a surface of the core part.
(3)

The photodetection element according to (2), in which the core part includes indium arsenide.
(4)

The photodetection element according to (2) or (3), in which the plurality of ligands includes at least one of 1,3-benzenedithiol, 1,4-benzenedithiol, 3-mercaptopropionic acid, 1,2-ethanedithiol, malonic acid, succinic acid, 3-mercaptobenzoic acid, 4-mercaptobenzoic acid, 3-aminobenzenethiol, or 4-aminobenzenethiol.
(5)

The photodetection element according to any one of (1) to (4), in which a change in an absorption peak wavelength derived from the binary semiconductor nanoparticle after heating at 150 °C for 210 minutes is within a range of 0 nm or more and 20 nm or less.
(6)

The photodetection element according to any one of (1) to (5), in which a peak of a boron fluoride ion, or BF₄⁻, is confirmed by a time-of-flight secondary ion mass spectrometry in the photoelectric conversion layer.
(7)

The photodetection element according to any one of (2) to (6), in which a surface coverage of the core part by the plurality of ligands is within a range of 84% or more and 100% or less.
(8)

The photodetection element according to any one of (1) to (7), in which
the first electrode, the photoelectric conversion layer, and the second electrode are stacked in this order toward a light incident side, and
the second electrode has a transmittance of 50% or more and 100% or less for a wavelength of 900 nm or more and 1600 nm or less.
(9)

The photodetection element according to any one of (1) to (8), in which
the first electrode, the photoelectric conversion layer, and the second electrode are stacked in this order toward the light incident side, and
the second electrode has a resistivity of 0 mΩ·m or more and 3.8 mΩ·-m or less.
(10)

The photodetection element according to any one of (1) to (9), in which
the first electrode, the photoelectric conversion layer, and the second electrode are stacked in this order toward the light incident side, and
the second electrode includes indium tin oxide or indium zinc oxide.
(11)

The photodetection element according to any one of (1) to (10), in which
the first electrode, the photoelectric conversion layer, and the second electrode are stacked in this order toward the light incident side, and
the second electrode has a thickness of 10 nm or more and 300 nm or less.
(12)

The photodetection element according to any one of (1) to (11), in which the photoelectric conversion layer has a light absorptivity of 20% or more at some or all of wavelength bands of 900 nm or more and 1600 nm or less.
(13)

The photodetection element according to any one of (1) to (12), in which
the first electrode, the photoelectric conversion layer, and the second electrode are stacked in this order toward the light incident side, and
the photodetection element further includes, between the first electrode and the photoelectric conversion layer, a charge block layer including an organic compound, an oxide semiconductor, or a semiconductor nanoparticle, the charge block layer selectively transporting, to the first electrode, one of positive or negative electric charge generated in the photoelectric conversion layer, the charge block layer inhibiting injection of another of the electric charge from a side of the first electrode.
(14)

The photodetection element according to (13), further including, between the first electrode and the charge block layer, a work function adjustment layer including an organic compound, an oxide semiconductor, or a semiconductor nanoparticle, the work function adjustment layer having an electron affinity or a work function lager than the first electrode.
(15)

The photodetection element according to any one of (1) to (13), in which
the first electrode, the photoelectric conversion layer, and the second electrode are stacked in this order toward the light incident side, and
the photodetection element further includes, between the second electrode and the photoelectric conversion layer, a charge block layer including an organic compound, an oxide semiconductor, or a semiconductor nanoparticle, the charge block layer selectively transporting, to the second electrode, one of positive or negative electric charge generated in the photoelectric conversion layer, the charge block layer inhibiting injection of another of the electric charge from a side of the second electrode.
(16)

The photodetection element according to (15), further including, between the second electrode and the charge block layer, a work function adjustment layer including an organic compound, an oxide semiconductor, or a semiconductor nanoparticle, the work function adjustment layer having an electron affinity or a work function lager than the second electrode.
(17)

A photodetection element including:
a first electrode;
a second electrode disposed to be opposed to the first electrode; and
a photoelectric conversion layer disposed between the first electrode and the second electrode, the photoelectric conversion layer including a binary semiconductor nanoparticle including indium, in which
a change in an absorption peak wavelength derived from the binary semiconductor nanoparticle after heating at 150 °C for 210 minutes is within a range of 0 nm or more and 20 nm or less.
(18)

A photodetection element including:
a first electrode;
a second electrode disposed to be opposed to the first electrode; and
a photoelectric conversion layer disposed between the first electrode and the second electrode, the photoelectric conversion layer including a plurality of quantum dots, in which
the plurality of quantum dots includes a core part and a plurality of ligands, the core part including a binary semiconductor nanoparticle including indium, the plurality of ligands being coordinated to a surface of the core part, and
a surface coverage of the core part by the plurality of ligands is within a range of 84% or more and 100% or less.
(19)

A photodetector including a plurality of pixels each including a photodetection element,
the photodetection element including
   a first electrode,
   a second electrode disposed to be opposed to the first electrode, and
   a photoelectric conversion layer disposed between the first electrode and the second electrode, the photoelectric conversion layer including fluorine and a binary semiconductor nanoparticle including indium, with an atomic number ratio of indium/fluorine being within a range of 100 or more and 150 or less.
(20)

An electronic apparatus including a photodetector that includes a plurality of pixels each including a photodetection element,
the photodetection element including
   a first electrode,
   a second electrode disposed to be opposed to the first electrode, and
   a photoelectric conversion layer disposed between the first electrode and the second electrode, the photoelectric conversion layer including fluorine and a binary semiconductor nanoparticle including indium, with an atomic number ratio of indium/fluorine being within a range of 100 or more and 150 or less.

The present application claims the benefit of Japanese Priority Patent Application JP2022-167093 filed with the Japan Patent Office on Oct. 18, 2022, the entire contents of which are incorporated herein by reference.

It should be understood by those skilled in the art that various modifications, combinations, sub-combinations, and alterations may occur depending on design requirements and other factors insofar as they are within the scope of the appended claims or the equivalents thereof.

1. A photodetection element comprising:
a first electrode;
a second electrode disposed to be opposed to the first electrode; and
a photoelectric conversion layer disposed between the first electrode and the second electrode, the photoelectric conversion layer including fluorine and a binary semiconductor nanoparticle including indium, with an atomic number ratio of indium/fluorine being within a range of 100 or more and 150 or less.

2. The photodetection element according to claim 1, wherein
the photoelectric conversion layer includes a plurality of quantum dots, and
the plurality of quantum dots includes a core part and a plurality of ligands, the core part including a binary semiconductor nanoparticle including the indium, the plurality of ligands being coordinated to a surface of the core part.

3. The photodetection element according to claim 2, wherein the core part includes indium arsenide.

4. The photodetection element according to claim 2, wherein the plurality of ligands includes at least one of 1,3-benzenedithiol, 1,4-benzenedithiol, 3-mercaptopropionic acid, 1,2-ethanedithiol, malonic acid, succinic acid, 3-mercaptobenzoic acid, 4-mercaptobenzoic acid, 3-aminobenzenethiol, or 4-aminobenzenethiol.

5. The photodetection element according to claim 1, wherein a change in an absorption peak wavelength derived from the binary semiconductor nanoparticle after heating at 150 °C for 210 minutes is within a range of 0 nm or more and 20 nm or less.

6. The photodetection element according to claim 1, wherein a peak of a boron fluoride ion, or BF₄⁻, is confirmed by a time-of-flight secondary ion mass spectrometry in the photoelectric conversion layer.

7. The photodetection element according to claim 2, wherein a surface coverage of the core part by the plurality of ligands is within a range of 84% or more and 100% or less.

8. The photodetection element according to claim 1, wherein
the first electrode, the photoelectric conversion layer, and the second electrode are stacked in this order toward a light incident side, and
the second electrode has a transmittance of 50% or more and 100% or less for a wavelength of 900 nm or more and 1600 nm or less.

9. The photodetection element according to claim 1, wherein
the first electrode, the photoelectric conversion layer, and the second electrode are stacked in this order toward a light incident side, and
the second electrode has a resistivity of 0 mQ-m or more and 3.8 mQ-m or less.

10. The photodetection element according to claim 1, wherein
the first electrode, the photoelectric conversion layer, and the second electrode are stacked in this order toward a light incident side, and
the second electrode includes indium tin oxide or indium zinc oxide.

11. The photodetection element according to claim 1, wherein
the first electrode, the photoelectric conversion layer, and the second electrode are stacked in this order toward a light incident side, and
the second electrode has a thickness of 10 nm or more and 300 nm or less.

12. The photodetection element according to claim 1, wherein the photoelectric conversion layer has a light absorptivity of 20% or more at some or all of wavelength bands of 900 nm or more and 1600 nm or less.

13. The photodetection element according to claim 1, wherein
the first electrode, the photoelectric conversion layer, and the second electrode are stacked in this order toward a light incident side, and
the photodetection element further comprises, between the first electrode and the photoelectric conversion layer, a charge block layer including an organic compound, an oxide semiconductor, or a semiconductor nanoparticle, the charge block layer selectively transporting, to the first electrode, one of positive or negative electric charge generated in the photoelectric conversion layer, the charge block layer inhibiting injection of another of the electric charge from a side of the first electrode.

14. The photodetection element according to claim 13, further comprising, between the first electrode and the charge block layer, a work function adjustment layer including an organic compound, an oxide semiconductor, or a semiconductor nanoparticle, the work function adjustment layer having an electron affinity or a work function lager than the first electrode.

15. The photodetection element according to claim 1, wherein
the first electrode, the photoelectric conversion layer, and the second electrode are stacked in this order toward a light incident side, and
the photodetection element further comprises, between the second electrode and the photoelectric conversion layer, a charge block layer including an organic compound, an oxide semiconductor, or a semiconductor nanoparticle, the charge block layer selectively transporting, to the second electrode, one of positive or negative electric charge generated in the photoelectric conversion layer, the charge block layer inhibiting injection of another of the electric charge from a side of the second electrode.

16. The photodetection element according to claim 15, further comprising, between the second electrode and the charge block layer, a work function adjustment layer including an organic compound, an oxide semiconductor, or a semiconductor nanoparticle, the work function adjustment layer having an electron affinity or a work function lager than the second electrode.

17. A photodetection element comprising:
a first electrode;
a second electrode disposed to be opposed to the first electrode; and
a photoelectric conversion layer disposed between the first electrode and the second electrode, the photoelectric conversion layer including a binary semiconductor nanoparticle including indium, wherein
a change in an absorption peak wavelength derived from the binary semiconductor nanoparticle after heating at 150 °C for 210 minutes is within a range of 0 nm or more and 20 nm or less.

18. A photodetection element comprising:
a first electrode;
a second electrode disposed to be opposed to the first electrode; and
a photoelectric conversion layer disposed between the first electrode and the second electrode, the photoelectric conversion layer including a plurality of quantum dots, wherein
the plurality of quantum dots includes a core part and a plurality of ligands, the core part including a binary semiconductor nanoparticle including indium, the plurality of ligands being coordinated to a surface of the core part, and
a surface coverage of the core part by the plurality of ligands is within a range of 84% or more and 100% or less.
